(19) United States
(12) Patent Application Publication
(10) Pub. No.: US 2025/0267953 A1
(43) Pub. Date: Aug. 21, 2025

(54) SEMICONDUCTOR DEVICE

(71) Applicant: ROHM CO., LTD., Kyoto (JP)

(72) Inventors: Kohei MORITA, Kyoto (JP); Satoki TANIGUCHI, Kyoto (JP); Kentaro NASU, Kyoto (JP); Keishi WATANABE, Kyoto (JP); Kentaro WAKI, Kyoto (JP)

(73) Assignee: ROHM CO., LTD., Kyoto (JP)

(21) Appl. No.: 19/053,435

(22) Filed: Feb. 14, 2025

(30) Foreign Application Priority Data
Feb. 19, 2024 (JP) 2024-023100

(51) Int. Cl. H10D 89/60; H01L 23/00

(52) U.S. Cl. CPC H10D 89/611; H01L 24/05; H01L 2224/04042; H01L 2224/05082

(57) ABSTRACT

A semiconductor device includes: a first diffusion region of an n-type formed in a surface layer portion of a first main surface; a second diffusion region of a p-type formed in the surface layer portion of the first main surface; an insulating layer formed on the first main surface to cover the first diffusion region and the second diffusion region; a first pad disposed on the insulating layer and electrically connected to the first diffusion region; and an internal parasitic capacitance former formed in the surface layer portion of the first main surface to face the first pad with the insulating layer interposed therebetween, wherein the first pad forms a parasitic capacitance, which is connected in series to an internal parasitic capacitance, at a location between the first pad and the insulating layer.

### CROSS-REFERENCE TO RELATED APPLICATION

This application is based upon and claims the benefit of priority from Japanese Patent Application No. 2024-023100, filed on Feb. 19, 2024, the entire contents of which are incorporated herein by reference.

### TECHNICAL FIELD

The present disclosure relates to a semiconductor device.

### BACKGROUND

There is known a semiconductor device including a semiconductor substrate and a transient voltage suppressor (TVS) circuit formed on the semiconductor substrate. The TVS circuit is configured by a plurality of diodes including a Zener diode.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is a cross-sectional view taken along line II-II in FIG. 1.

FIG. 3 is a cross-sectional view taken along line III-III in FIG. 1.

FIG. 4 is a plan view showing a layout of a first pad and a second pad.

FIG. 5 is a plan view showing a layout of a first wiring layer.

FIG. 6 is a plan view showing a layout of a chip.

FIG. 7 is an enlarged view of a portion surrounded by one-dot chain line VII in FIG. 6.

FIG. 8A is a cross-sectional view taken along line VIIIA-VIIIA in FIG. 7.

FIG. 8B is an enlarged view of a portion surrounded by one-dot chain line VIIIB in FIG. 8A.

FIG. 9 is a cross-sectional view taken along line IX-IX in FIG. 6.

FIG. 10 is an enlarged view of a portion surrounded by one-dot chain line X in FIG. 9.

FIG. 11 is an electrical circuit diagram of the semiconductor device.

FIG. 12 is an electrical circuit diagram showing parasitic capacitances around a first pad.

FIG. 13 is a schematic plan view of a diode chip included in a semiconductor device according to a second embodiment of the present disclosure, and a view corresponding to FIG. 6.

FIG. 14 is a cross-sectional view taken along line XIV-XIV shown in FIG. 13.

FIG. 15 is an enlarged view of a portion surrounded by one-dot chain line XV in FIG. 14.

FIG. 16 is a schematic plan view of a diode chip included in a semiconductor device according to a third embodiment of the present disclosure, and a view corresponding to FIG. 6.

FIG. 17 is a cross-sectional view taken along line XVII-XVII shown in FIG. 16.

FIG. 18 is an enlarged view of a portion surrounded by one-dot chain line XVIII in FIG. 17.

FIG. 19 is a schematic plan view of a diode chip included in a semiconductor device according to a fourth embodiment of the present disclosure, and a view corresponding to FIG. 6.

FIG. 20A is a cross-sectional view taken along line XX-XX in FIG. 19.

FIG. 20B is a cross-sectional view taken along line XX-XX in FIG. 19.

FIG. 21 is an electrical circuit diagram showing parasitic capacitances around a first pad according to the fourth embodiment.

FIG. 22 is a schematic plan view of a chip included in a semiconductor device according to a fifth embodiment of the present disclosure, and a view corresponding to FIG. 6.

FIG. 23 is a cross-sectional view taken along line XXIII-XXIII in FIG. 22.

FIG. 24 is an electrical circuit diagram showing parasitic capacitances around a first pad according to the fifth embodiment.

FIG. 25 is a schematic cross-sectional view of a semiconductor device according to a modification (first modification) of the first embodiment of the present disclosure, and a view corresponding to FIG. 10.

FIG. 26 is an electrical circuit diagram showing parasitic capacitances around a first pad according to the first modification.

FIG. 27 is a schematic cross-sectional view of a semiconductor device according to a modification (second modification) of the first embodiment of the present disclosure, and a view corresponding to FIG. 9.

FIG. 28 is a schematic cross-sectional view of a semiconductor device according to a modification (third modification) of the second embodiment of the present disclosure, and a view corresponding to FIG. 15.

FIG. 29 is a schematic cross-sectional view of a semiconductor device according to a modification (fourth modification) of the second embodiment of the present disclosure, and a view corresponding to FIG. 15.

FIG. 30 is a schematic cross-sectional view of a semiconductor device according to a modification (fifth modification) of the second embodiment of the present disclosure, and a view corresponding to FIG. 14.

FIG. 31 is a schematic cross-sectional view of a semiconductor device according to a modification (sixth modification) of the fifth embodiment of the present disclosure, and a view corresponding to FIG. 23.

FIG. 32 is a schematic cross-sectional view of a semiconductor device according to a modification (seventh modification) of the fifth embodiment of the present disclosure, and a view corresponding to FIG. 23.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, embodiments of the present disclosure will be described in detail with reference to the accompanying drawings.

The accompanying drawings are all schematic diagrams and are not strictly illustrating diagrams. The scale, ratio, angle, and the like do not necessarily match. Corresponding structures among the accompanying drawings are designated by same reference numerals, and duplicated descriptions thereof are omitted or simplified. For the structures whose descriptions are omitted or simplified, the descriptions given before the omission or simplification apply.

When the term “substantially” is used in this specification, this term includes a numerical value (form) approximately equal to a numerical value (form) of a comparison target, as well as a numerical error (form error) within a range of +10% based on the numerical value (form) of the comparison target. In the following descriptions, terms such as “first,” “second,” and “third,” etc. are used. These terms are symbols attached to names of individual structures to clarify an order of descriptions, and are not intended to limit the names of the individual structures.

In the following descriptions, a conductivity type of a semiconductor (impurity) is indicated by using “p-type” or “n-type.” “P-type” may be referred to as “first conductivity type” and “n-type” may be referred to as “second conductivity type.” Of course, “n-type” may be referred to as “first conductivity type” and “p-type” may be referred to as “second conductivity type.” “N-type” is a conductivity type derived from a pentavalent element, and “p-type” is a conductivity type derived from a trivalent element. Unless otherwise specified, the trivalent element is at least one of boron, aluminum, gallium, or indium. Unless otherwise specified, the pentavalent element is at least one of nitrogen, phosphorus, arsenic, antimony, or bismuth.

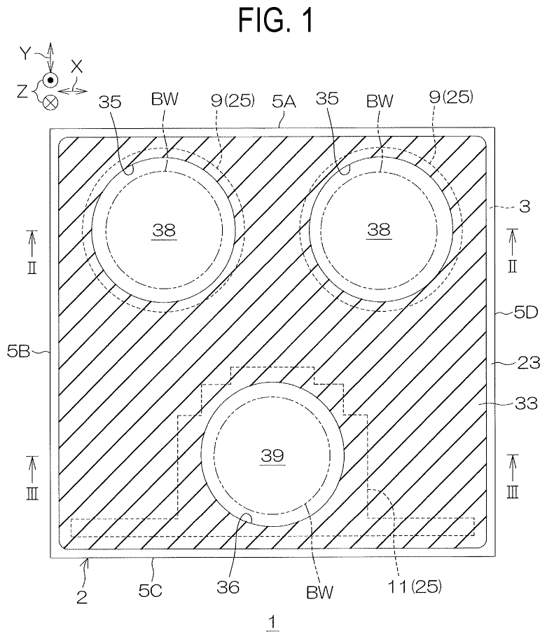

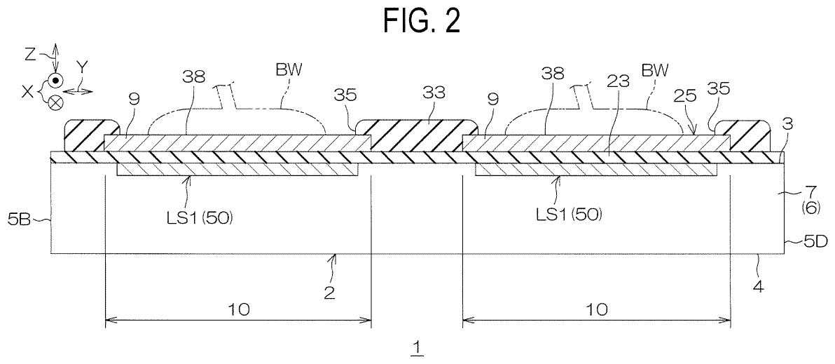

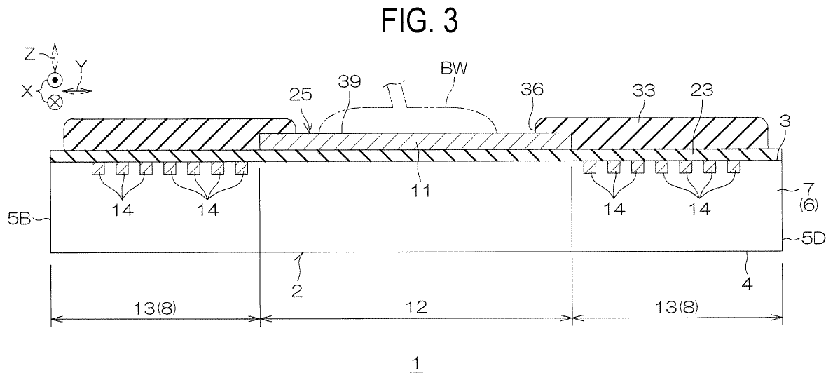

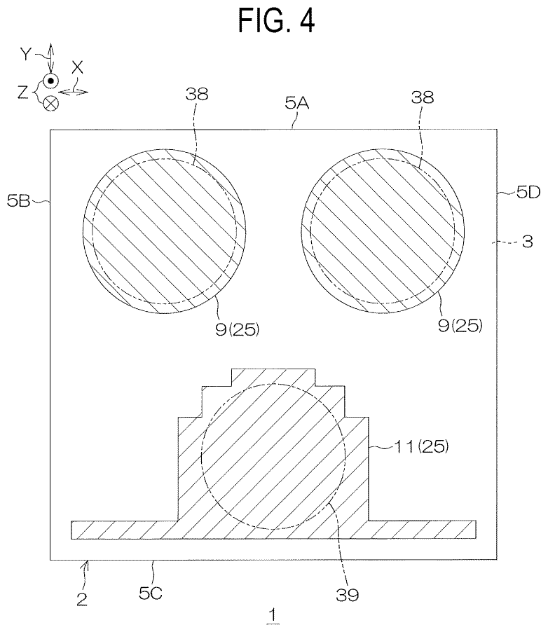

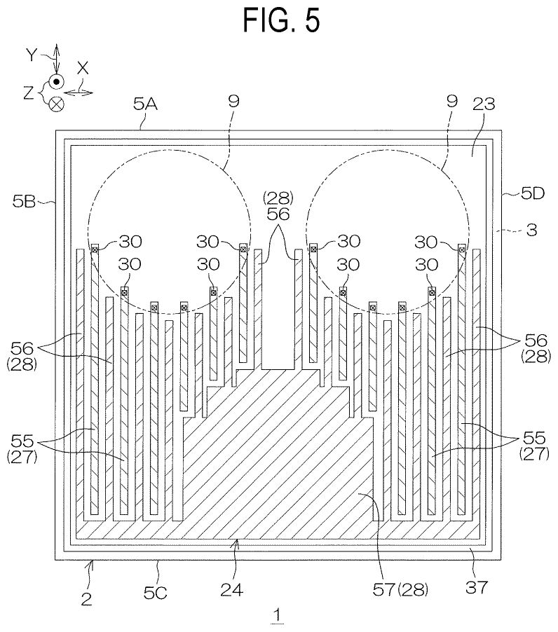

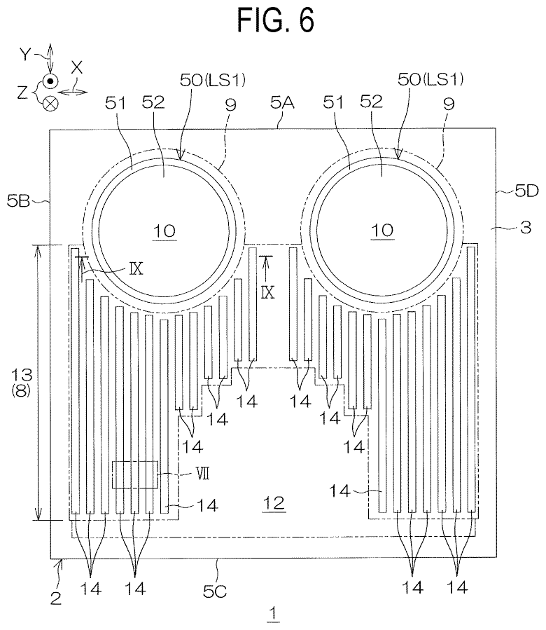

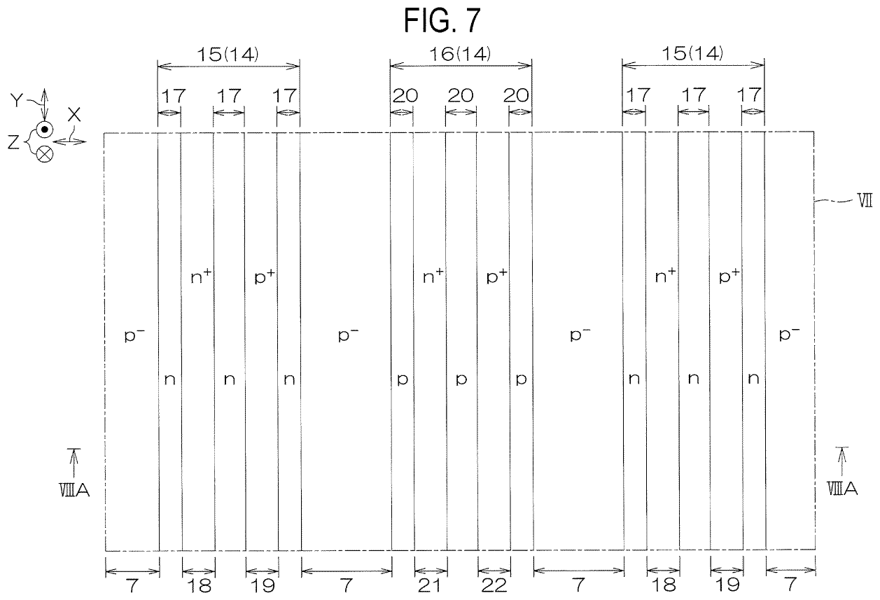

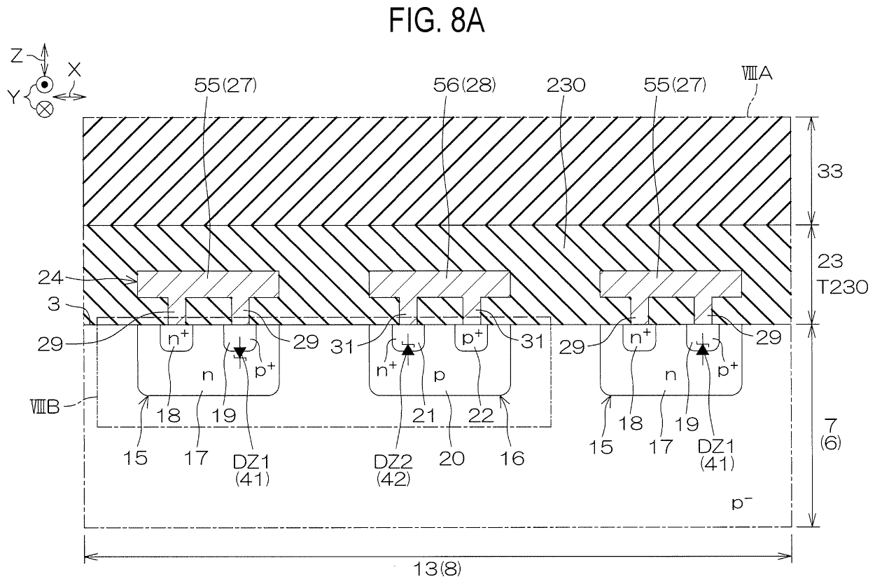

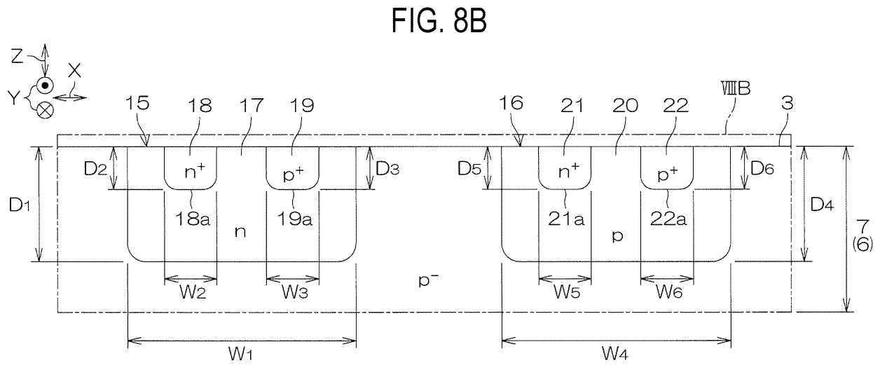

FIG. 1 is a schematic plan view of a semiconductor device 1 according to a first embodiment of the present disclosure. FIG. 2 is a cross-sectional view taken along line II-II in FIG. 1. FIG. 3 is a cross-sectional view taken along line III-III in FIG. 1. FIG. 4 is a plan view showing a layout of a first pad 9 and a second pad 11. FIG. 5 is a plan view showing a layout of a first wiring layer 24. FIG. 6 is a plan view showing a layout of a chip 2. FIG. 7 is an enlarged view of a portion surrounded by one-dot chain line VII in FIG. 6. FIG. 8A is a cross-sectional view taken along line VIIIA-VIIIA in FIG. 7. FIG. 8B is an enlarged view of a portion surrounded by one-dot chain line VIIIB in FIG. 8A.

The semiconductor device 1 includes the chip 2. The chip 2 may be called a “semiconductor chip,” a “diode chip,” or the like. The semiconductor device 1 is a small chip component (semiconductor device). In this embodiment, the semiconductor device 1 is made of an electrostatic discharge (ESD) protection chip that protects an electric circuit from ESD. The ESD protection chip protects the electric circuit by discharging an applied ESD surge to a power supply wiring or a ground wiring.

The semiconductor device 1 may be referred to as a “diode,” a “TVS diode,” a “diode chip,” or the like.

The chip 2 has a first main surface (main surface) 3 on one side, a second main surface 4 on the other side, and first to fourth side surfaces 5A to 5D that connect the first main surface 3 and the second main surface 4. The first main surface 3 and the second main surface 4 are formed in a quadrangular shape in a plan view seen from a vertical direction Z (hereinafter simply referred to as “plan view”). The vertical direction Z is also a thickness direction of the chip 2 and a direction normal to the first main surface 3 (second main surface 4). The first main surface 3 and the second main surface 4 may be formed in a square or rectangular shape in a plan view. In this embodiment, the first main surface 3 and the second main surface 4 are formed in a square shape (substantially square shape) in a plan view.

Referring to FIG. 1, in a circumferential direction of the chip 2 starting from the first side surface 5A (counterclockwise in FIG. 1), the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X along the first main surface 3 and face a second direction Y intersecting (specifically, perpendicular to) the first direction X. The second side surface 5B and the fourth side surface 5D extend in the second direction Y and face the first direction X. The first to fourth side surfaces 5A to 5D are flat surfaces extending along the vertical direction Z.

The first to fourth side surfaces 5A to 5D may have a length of 0.1 mm to 2 mm in a plan view. The length may be 0.1 mm or more and 0.2 mm or less, 0.2 mm or more and 0.3 mm or less, 0.3 mm or more and 0.4 mm or less, 0.4 mm or more and 0.5 mm or less, 0.5 mm or more and 0.6 mm or less, 0.6 mm or more and 0.7 mm or less, 0.7 mm or more and 0.8 mm or less, 0.8 mm or more and 0.9 mm or less, 0.9 mm or more and 1 mm or less, 1 mm or more and 1.2 mm or less, 1.2 mm or more and 1.4 mm or less, 1.4 mm or more and 1.6 mm or less, 1.6 mm or more and 1.8 mm or less, or 1.8 mm or more and 2 mm or less.

Referring to FIG. 2, the chip 2 includes a p-type (first conductivity type) semiconductor layer 6. The p-type semiconductor layer 6 is exposed from the second main surface 4 and the first to fourth side surfaces 5A to 5D. The semiconductor layer 6 may be referred to as a “base region,” a “semiconductor region,” or the like.

In this embodiment, the semiconductor layer 6 is made of a p-type semiconductor substrate 7. A p-type impurity concentration of the semiconductor substrate 7 is 1×10¹² cm⁻³ or more and 1×10¹⁴ cm⁻³ or less. The semiconductor substrate 7 is, specifically, a silicon substrate. The semiconductor substrate 7 forms a surface layer portion of the first main surface 3 of the chip 2 and a surface layer portion of the second main surface 4. The p-type impurity concentration of the semiconductor substrate 7 may be 1.0×10¹³ cm⁻³ or more and 1.0×10¹⁵ cm⁻³ or less. Since the semiconductor substrate 7 has a relatively low p-type impurity concentration, it may be referred to as a “p⁻ type region.” A thickness of the semiconductor substrate 7 may be 10 μm or more and 800 μm or less.

Referring to FIG. 6, a device formation region 8 in which a diode device is formed on the surface layer portion of the first main surface 3, two first pad regions 10 in which first pads 9 are disposed on the first main surface 3, and one second pad region 12 in which the second pad 11 is disposed on the first main surface 3 are set in the chip 2. The device formation region 8, the first pad regions 10, and the second pad region 12 do not overlap with one another. In this embodiment, the device formation region 8 is a thyristor region 13 in which a thyristor (reverse conducting thyristor) is formed.

The thyristor region 13 is set in an inner portion of the chip 2 with a gap from a peripheral edge (first to fourth side surfaces 5A to 5D) of the chip 2 in a plan view. The two first pad regions 10 are regions on a side of the first side surface 5A as viewed from a center of the chip 2, and formed in a region extending from the second side surface 5B to the fourth side surface 5D. In addition, the one second pad region 12 is a region on a side of the third side surface 5C as viewed from the center of the chip 2, and is formed in a region spaced apart from both the second side surface 5B and the fourth side surface 5D. The thyristor region 13 is formed in a region excluding these regions.

A first area ratio of a plan-view area of the thyristor region 13 to a plan-view area of the first main surface 3 may be 25% or more and 80% or less. The first area ratio may be 25% or more and 30% or less, 30% or more and 35% or less, 35% or more and 40% or less, 40% or more and 45% or less, 45% or more and 50% or less, 50% or more and 55% or less, 55% or more and 60% or less, 60% or more and 65% or less, 65% or more and 70% or less, 70% or more and 75% or less, or 75% or more and 80% or less. The first area ratio may be 40% or more and 70% or less.

The semiconductor device 1 includes a plurality of thyristor structures 14 in the thyristor region 13. The thyristor structures 14 are disposed at intervals inward from the peripheral edge of the thyristor region 13. In this embodiment, the thyristor structures 14 are arranged at intervals in the first direction X and formed in a stripe shape extending in the second direction Y. That is, in this embodiment, the thyristor structures 14 are arranged in a stripe shape extending in the second direction Y. It goes without saying that the number of the thyristor structures 14 is not limited to the number shown in FIG. 6 and may be a greater number (e.g., multiple numbers).

Referring to FIG. 7, the thyristor structures 14 include a plurality of first thyristor structures 15 and a plurality of second thyristor structures 16. The first thyristor structures 15 extend linearly in the second direction Y. The second thyristor structures 16 extend linearly in the second direction Y. The first thyristor structures 15 and the second thyristor structures 16 are arranged alternately in the first direction X. The first thyristor structures 15 are arranged in a stripe shape. The second thyristor structures 16 are arranged in a stripe shape.

Referring to FIGS. 7 and 8A, the first thyristor structure 15 includes a first diffusion region 17 formed in the first main surface 3. An n-type impurity concentration of the first diffusion region 17 is 1.0×10¹⁶ cm⁻³ or more and 1.0×10¹⁸ cm⁻³ or less. The n-type impurity concentration of the first diffusion region 17 is higher than the p-type impurity concentration of the semiconductor substrate 7. The first diffusion region 17 may be referred to as an “n-type well region.” The first diffusion region 17 extends linearly in the second direction Y.

Referring to FIG. 8B, the first diffusion region 17 has a first width W₁ in the first direction X. The first width W₁ is, for example, 5 μm or more and 20 μm or less. A first depth D₁ of a bottom 17a of the first diffusion region 17 is, for example, 1 μm or more and 5 μm or less.

Referring to FIGS. 7 and 8A, the first thyristor structure 15 includes an n-type base region 18 and a p-type emitter region 19, which are formed in a surface layer portion of the first diffusion region 17. The n-type base region 18 and the p-type emitter region 19 extend linearly in the second direction Y. The p-type emitter region 19 and the n-type base region 18 are formed with a gap in the first direction X. The n-type base region 18 is disposed on a side of the second side surface 5B with respect to the p-type emitter region 19. The n-type base region 18 is formed with a gap from a peripheral edge of the first diffusion region 17 on the side of the second side surface 5B. The p-type emitter region 19 is formed with a gap from a peripheral edge of the first diffusion region 17 on a side of the fourth side surface 5D.

An n-type impurity concentration of the n-type base region 18 is 1.0×10¹⁹ cm⁻³ or more and 1.0×10²⁰ cm⁻³ or less. The n-type impurity concentration of the n-type base region 18 is higher than the n-type impurity concentration of the first diffusion region 17. The n-type base region 18 may be referred to as an “n-type high concentration region,” a “first base region,” a “base region,” or the like.

Referring to FIG. 8B, the n-type base region 18 has a second width W₂ in the first direction X. The second width W₂ of the n-type base region 18 is, for example, 0.5 μm or more and 3 μm or less. The second width W₂ is narrower than the first width W₁ (W₂<W₁).

A second depth D₂ of a bottom 18a of the n-type base region 18 is, for example, 0.5 μm or more and 2 μm or less. The second depth D₂ is smaller than the first depth D₁ (D₂<D₁).

Referring to FIGS. 7 and 8A, a p-type impurity concentration of the p-type emitter region 19 is 1.0×10¹⁹ cm⁻³ or more and 1.0×10²⁰ cm⁻³ or less. The p-type impurity concentration of the p-type emitter region 19 is higher than the p-type impurity concentration of the semiconductor substrate 7. The p-type impurity concentration of the p-type emitter region 19 is higher than a p-type impurity concentration of a second diffusion region 20 to be described later. The p-type emitter region 19 may also be referred to as a “p-type high concentration region,” a “first emitter region,” an “emitter region,” or the like.

Referring to FIG. 8B, the p-type emitter region 19 has a third width W₃ in the first direction X. The third width W₃ is, for example, 0.5 μm or more and 3 μm or less. The third width W₃ is narrower than the first width W₁ (W₃<W₁). In this embodiment, the third width W₃ is equal to the second width W₂ (W₃=W₂).

A third depth D₃ of a bottom 19a of the p-type emitter region 19 is, for example, 0.5 μm or more and 2 μm or less. The third depth D₃ is smaller than the first depth D₁ (D₃<D₁). In this embodiment, the third depth D₃ is equal to the second depth D₂ (D₃=D₂).

Referring to FIGS. 7 and 8A, the second thyristor structure 16 includes the second diffusion region 20 formed in the first main surface 3. The p-type impurity concentration of the second diffusion region 20 is 1.0×10¹⁶ cm⁻³ or more and 1.0×10¹⁸ cm⁻³ or less. The p-type impurity concentration of the second diffusion region 20 is higher than the p-type impurity concentration of the semiconductor substrate 7. The second diffusion region 20 may be referred to as a “p-type well region.” The second diffusion region 20 extends linearly in the second direction Y.

Referring to FIG. 8B, the second diffusion region 20 has a fourth width W₄ in the first direction X. The fourth width W₄ is, for example, 5 μm or more and 20 μm or less. In this embodiment, the fourth width W₄ is equal to the first width W₁ (W₄=W₁). A fourth depth D₄ of a bottom 20a of the second diffusion region 20 is, for example, 1 μm or more and 5 μm or less. The fourth depth D₄ is equal to the first depth D₁ (D₄=D₁).

Referring to FIGS. 7 and 8A, the second thyristor structure 16 includes an n-type emitter region 21 and a p-type base region 22, which are formed in a surface layer portion of the second diffusion region 20. The n-type emitter region 21 and the p-type base region 22 extend linearly in the second direction Y. The p-type base region 22 is formed with a gap from the n-type emitter region 21 in the first direction X. The n-type emitter region 21 is disposed on a side of the second side surface 5B with respect to the p-type base region 22. The n-type emitter region 21 is formed with a gap from a peripheral edge of the second diffusion region 20 on the side of the second side surface 5B. The p-type base region 22 is formed with a gap from a peripheral edge of the second diffusion region 20 on a side of the fourth side surface 5D.

An n-type impurity concentration of the n-type emitter region 21 is 1.0×10¹⁹ cm⁻³ or more and 1.0×10²⁰ cm⁻³ or less. The n-type impurity concentration of the n-type emitter region 21 is higher than the p-type impurity concentration of the second diffusion region 20. The n-type emitter region 21 may be referred to as an “n-type high concentration region,” a “high concentration region,” an “emitter region,” or the like.

Referring to FIG. 8B, the n-type emitter region 21 has a fifth width W₅ in the first direction X. The fifth width W₅ of the n-type emitter region 21 is, for example, 0.5 μm or more and 3 μm or less. The fifth width W₅ is narrower than the fourth width W₄ (W₅<W₄). In this embodiment, the fifth width W₅ is equal to the second width W₂ (W₅=W₂).

A fifth depth D₅ of a bottom 21a of the n-type emitter region 21 is, for example, 0.5 μm or more and 2 μm or less. The fifth depth D₅ is smaller than the fourth depth D₄ (D₅<D₄). In this embodiment, the fifth depth D₅ is equal to the second depth D₂ (D₅=D₂).

Referring to FIGS. 7 and 8A, the p-type impurity concentration of the p-type base region 22 is 1.0×10¹⁹ cm⁻³ or more and 1.0×10²⁰ cm⁻³ or less. The p-type impurity concentration of the p-type base region 22 is higher than the p-type impurity concentration of the semiconductor substrate 7. The p-type impurity concentration of the p-type base region 22 is higher than the p-type impurity concentration of the second diffusion region 20. The p-type base region 22 may be referred to as a “p-type high concentration region,” a “second base region,” a “base region,” or the like.

The p-type base region 22 has a sixth width W₆ in the first direction X. The sixth width W₆ is, for example, 0.5 μm or more and 3 μm or less. The sixth width W₆ is narrower than the fourth width W₄ (W₆<W₄). In this embodiment, the sixth width W₆ is equal to the third width W₃ (W₆=W₃). The sixth width W₆ is equal to the fifth width W₅ (W₆=W₅).

Referring to FIG. 8B, a sixth depth D₆ of a bottom 22a of the p-type base region 22 is, for example, 0.5 μm or more and 2 μm or less. The sixth depth Do is smaller than the fourth depth D₄ (D₆<D₄). In this embodiment, the sixth depth De is equal to the third depth D₃ (D₆=D₃). The sixth depth D₆ is equal to the fifth depth D₅ (D₆=D₅).

Referring to FIGS. 2 and 8A, the semiconductor device 1 (chip 2) includes an insulating layer 23 that covers the first main surface 3. The insulating layer 23 collectively covers the device formation region 8 (thyristor region 13), the two first pad regions 10, and the one second pad region 12. The insulating layer 23 covers the thyristor structures 14 (the first thyristor structures 15 and the second thyristor structures 16) in the thyristor region 13. The insulating layer 23 may be referred to as an “interlayer insulating film,” “insulating film,” “interlayer film,” “intermediate insulating film,” or the like.

In this embodiment, the insulating layer 23 is configured as a laminated wiring structure having a laminated structure in which a plurality of insulating layers and a plurality of wiring layers are laminated alternately. Each insulating layer 23 may include at least one of a silicon oxide film, a silicon nitride film, or a silicon oxynitride film. In this embodiment, each insulating layer 23 includes a silicon oxide film.

A thickness of the insulating layer 23 (a thickness T230 of an upper portion 230 described later (see FIG. 8A)) may be 3 μm or more and 30 μm or less. The thickness of the insulating layer 23 may be 1 μm or more and 2 μm or less, 2 μm or more and 4 μm or less, 4 μm or more and 6 μm or less, 6 μm or more and 8 μm or less, 8 μm or more and 10 μm or less, 10 μm or more and 15 μm or less, 15 μm or more and 20 μm or less, 20 μm or more and 25 μm or less, or 25 μm or more and 30 μm or less. The thickness of the insulating layer 23 may be 5 μm or more and 15 μm or less.

The insulating layer 23 includes the first wiring layer 24 (see FIG. 8A) disposed anywhere above the first main surface 3 via an insulating layer, and a second wiring layer 25 (see FIG. 2) disposed above the first wiring layer 24 via an insulating layer. All of the wirings included in the first wiring layer 24 have the same height from the first main surface 3. All of the wirings included in the second wiring layer 25 have the same height from the first main surface 3. The first wiring layer 24 and the second wiring layer 25 have different heights from the first main surface 3.

Referring to FIGS. 1 and 4, the semiconductor device 1 includes the two first pads (pads) 9 disposed on the insulating layer 23. The first pads 9 are metal pads, and in this embodiment, the first pads 9 are made of a metallic material containing Al (aluminum).

In this embodiment, the first pad 9 is formed in a circular shape in a plan view. The first pad 9 has a peripheral edge portion. The first pad 9 may be referred to as a “first metal,” a “first pad,” a “first electrode,” or the like. The first pad 9 is included in the second wiring layer 25.

Referring to FIG. 4, the two first pads 9 are disposed in a region on a side of the first side surface 5A with respect to the thyristor region 13 (see FIG. 6) in a plan view. The two first pads 9 are formed with a gap in the first direction X. That is, the first pads 9 include the first pad 9 on a side of the second side surface 5B and the first pad 9 on a side of the fourth side surface 5D. The first pad 9 on the side of the second side surface 5B is disposed with a narrow gap from the second side surface 5B. The first pad 9 on the side of the fourth side surface 5D is disposed with a narrow gap from the fourth side surface 5D.

When a center line is set to cross a center position in the first direction X of the chip 2 in the second direction Y, the two first pads 9 may be formed in a layout that is linearly symmetrical with respect to the center line. The two first pads 9 may have the same size.

Referring to FIGS. 1 and 4, the semiconductor device 1 includes the one second pad (pad) 11 disposed on the insulating layer 23. The second pad 11 is a metal pad, and in this embodiment, the second pad 11 is made of a metallic material including Al (aluminum). The second pad 11 functions as a cathode electrode. In this embodiment, the second pad 11 is formed in a circular shape in a plan view. The second pad 11 may be referred to as a “second metal,” a “second pad,” a “second electrode,” or the like. The second pad 11 is included in the second wiring layer 25.

Referring to FIG. 4, the one second pad 11 is disposed in a region on a side of the third side surface 5C with respect to the thyristor region 13 (see FIG. 6) in a plan view. The second pads 11 are disposed with a narrow gap from the third side surface 5C. The second pads 11 may be formed in a layout in which a center of the second pad 11 is located on a center line that crosses a center of the chip 2 in the second direction Y. In this embodiment, the second pad 11 has a polygonal shape that is wide in both the first direction X and the second direction Y in a plan view.

Referring to FIG. 5, the semiconductor device 1 includes, in the insulating layer 23, a first connection structure 27 that electrically connects the first thyristor structures 15 (see FIG. 7) to the first pads 9, and a second connection structure 28 that electrically connects the second thyristor structures 16 (see FIG. 7) to the second pad 11. In this embodiment, the first connection structure 27 includes a plurality of first connection wirings 55 arranged in a stripe shape extending in the second direction Y. The first connection wirings 55 are included in the first wiring layer 24 (see FIG. 8A).

Referring to FIGS. 5 and 8A, the first connection wiring 55 extends linearly in the second direction Y. The first connection wiring 55 is disposed above the first thyristor structure 15. The first connection wiring 55 overlaps with the first thyristor structure 15 in a plan view. The first connection wiring 55 is electrically connected to the n-type base region 18 and the p-type emitter region 19 of the first thyristor structure 15 via a first lower via 29 (see FIG. 8A).

An end of the first connection wiring 55 (an end on a side of the first side surface 5A) reaches a region facing a lower side of the first pad 9, and is connected to the first pad 9 in that region via a first upper via 30 (see FIG. 5). In other words, the first connection wiring 55 electrically connects the n-type base region 18 (see FIG. 8A) and the p-type emitter region 19 (see FIG. 8A) of the first thyristor structure 15 to the first pad 9.

The first connection wiring 55 faces only a portion of the first pad 9 (a portion where the first upper via 30 (see FIG. 5) is formed). That is, in a plan view, most of the first pad 9 does not overlap with the first connection wiring 55. Therefore, the presence of the first connection wiring 55 has almost no influence on a parasitic capacitance between the first pad 9 and the insulating layer 23.

Referring to FIG. 5, in this embodiment, the second connection structure 28 includes a plurality of second connection wirings 56 arranged in a stripe shape extending in the second direction Y, and a pad wiring 57 having a shape (a polygonal shape wide in both the first direction X and the second direction Y) that matches the second pad 11 (see FIG. 4) in a plan view. The second connection wirings 56 are drawn out from the pad wiring 57 in the second direction Y. The second connection wirings 56 and the pad wiring 57 are included in the first wiring layer 24 (see FIG. 8A).

In this embodiment, since the second pad 11 is at the same potential as the second diffusion region 20, no parasitic capacitance is formed between the second pad 11 and the semiconductor substrate 7. Thus, the second pad region 12 is not a region that forms a parasitic capacitance with the second pad 11. Therefore, no particular problem occurs even when the pad wiring 57 facing the second pad 11 in a plan view is provided.

Referring to FIGS. 5 and 8A, the second connection wiring 56 extends linearly in the second direction Y. The second connection wiring 56 is disposed above the second thyristor structure 16. The second connection wiring 56 overlaps with the second thyristor structure 16 in a plan view.

The second connection wiring 56 is electrically connected to the n-type emitter region 21 and the p-type base region 22 of the second thyristor structure 16 via a second lower via 31 (see FIG. 8A). The pad wiring 57 is electrically connected to the second pad 11 via a second upper via (not shown). With this configuration, the second connection structure 28 electrically connects the n-type emitter region 21 and the p-type base region 22 of the second thyristor structure 16 to the second pad 11.

By the p-type emitter region 19 and the first n-type diffusion region 17, a first pn junction 41 is formed in a surface layer portion of the thyristor region 13. The first pn junction 41 forms a first Zener diode DZ1 in the thyristor region 13.

By the second p-type diffusion region 20 and the n-type emitter region 21, a second pn junction 42 is formed in the surface layer portion of the thyristor region 13. The second pn junction 42 forms a second Zener diode DZ2 in the thyristor region 13.

Referring to FIGS. 1 and 2, the semiconductor device 1 includes an upper insulating film 33 selectively covering the first pads 9 and the second pad 11 on the first main surface 3. The upper insulating film 33 includes first pad openings 35 that expose inner portions of the first pads 9. The first pad openings 35 are formed in a circular shape in a plan view. The upper insulating film 33 covers peripheral edge portions of the first pads 9. First electrode surfaces 38 are formed by exposing the inner portions of the first pads 9 via the first pad openings 35. Connectors (e.g., bonding wires) BW are connected to the first electrode surfaces 38.

The upper insulating film 33 includes a second pad opening 36 that exposes an inner portion of the second pad 11. The second pad opening 36 is formed in a circular shape in a plan view. The upper insulating film 33 covers a peripheral edge portion of the second pad 11. A second electrode surface 39 is formed by exposing the inner portion of the second pad 11 via the second pad opening 36. A connector BW is connected to the second electrode surface 39.

The upper insulating film 33 has an outer peripheral edge at a position spaced apart from the first to fourth side surfaces 5A to 5D. The insulating layer 23 is exposed between the outer peripheral edge of the upper insulating film 33 and the first to fourth side surfaces 5A to 5D. The exposed portion of the insulating layer 23 has an annular shape (specifically, a rectangular ring shape).

The upper insulating film 33 may have a thickness greater than a thickness of the first pads 9 and a thickness of the second pad 11. The thickness of the upper insulating film 33 may be less than a thickness of the chip 2.

The upper insulating film 33 may have a laminated structure in which an inorganic insulating film and an organic insulating film are laminated in this order from a side of the chip 2. The upper insulating film 33 may include at least one of an inorganic insulating film or an organic insulating film, and does not necessarily have to include an inorganic insulating film and an organic insulating film at the same time. The inorganic insulating film may include at least one of a silicon oxide film, a silicon nitride film, or a silicon oxynitride film. The inorganic insulating film may include an insulating material different from that of the insulating layer 23. The organic insulating film may be made of a polyimide film, a polyamide film, or a polybenzoxazole film. In this embodiment, the organic insulating film includes a polybenzoxazole film.

Referring to FIG. 5, a shield ring 37 is formed at a peripheral edge of the semiconductor device 1 in the insulating layer 23. The shield ring 37 is formed in a rectangular ring shape along the first to fourth side faces 5A to 5D. In a plan view, the thyristor region 13, the first pad regions 10, and the second pad region 12 are surrounded by the shield ring 37. The shield ring 37 is, for example, a shield wiring included in the insulating layer 23. When dicing the semiconductor device to obtain chips, cracks or defects may be generated on a peripheral edge portion of the chip. When the cracks or defects are generated on the peripheral edge portion of the chip, moisture may easily enter from outside. Therefore, in this embodiment, the shield ring 37 is formed at the peripheral edge of the insulating layer 23 in a rectangular ring shape in a plan view.

A laminated parasitic capacitance former (internal parasitic capacitance former) 50 is formed on the first main surface 3 in the thyristor region 13.

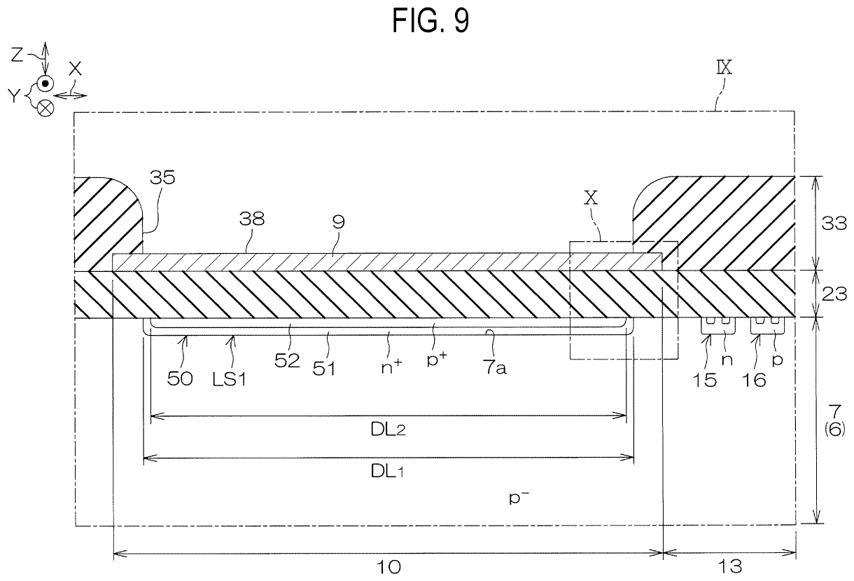

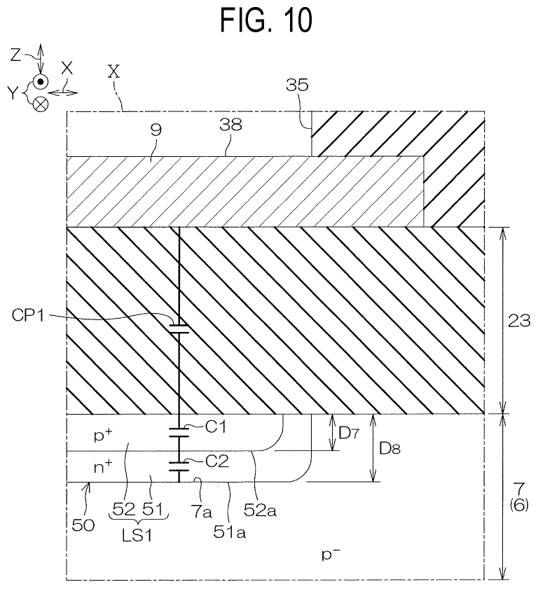

FIG. 9 is a cross-sectional view taken along line IX-IX in FIG. 6. FIG. 10 is an enlarged view of a portion surrounded by one-dot chain line X in FIG. 9. The laminated parasitic capacitance former 50 will be described with reference to FIGS. 6, 9 and 10.

The laminated parasitic capacitance former 50 has a laminated structure LS1 of an n-type first diffusion layer 51 and a p-type second diffusion layer 52. The laminated structure LS1 (laminated parasitic capacitance former 50) forms a parasitic capacitance between the semiconductor substrate 7 and the first main surface 3.

In this embodiment, the laminated structure LS1 is circular in a plan view. The laminated structure LS1 overlaps with the first pad 9 in a plan view. A peripheral edge of the laminated structure LS1 is located inward of a peripheral edge of the first pad 9 in a plan view. More specifically, the laminated structure LS1 overlaps with the first electrode surface 38 in a plan view. A peripheral edge portion of the laminated structure LS1 is aligned with a peripheral edge of the first electrode surface 38 in a plan view.

Referring to FIGS. 6 and 9, the first diffusion layer 51 is a lower layer of the laminated structure LS1. The first diffusion layer 51 is formed on the first main surface 3. In this embodiment, the first diffusion layer 51 is circular in a plan view. A peripheral edge of the first diffusion layer 51 is the peripheral edge of the laminated structure LS1. An n-type impurity concentration of the first diffusion layer 51 is 1.0×10¹⁶ cm⁻³ or more and 1.0×10¹⁸ cm⁻³ or less. The n-type impurity concentration of the first diffusion layer 51 is higher than the p-type impurity concentration of the semiconductor substrate 7. In this embodiment, the n-type impurity concentration of the first diffusion layer 51 is the same as the n-type impurity concentration of the first diffusion region 17.

Referring to FIG. 9, a first diameter (width) DL₁ of the first diffusion layer 51 is, for example, 250 μm or more and 1 mm or less. The first diameter DL₁ is larger than the first width W₁ (see FIG. 8B) of the first diffusion region 17 (DL₁>W₁). The first diameter DL₁ is larger than the fourth width W₄ (see FIG. 8B) of the second diffusion region 20 (DL₁>W₄).

Referring to FIG. 10, a seventh depth D₇ of a bottom 51a of the first diffusion layer 51 is, for example, 1 μm or more and 5 μm or less. In this embodiment, the seventh depth D₇ is equal to the first depth D₁ (see FIG. 8B) of the bottom 17a of the first diffusion region 17 and the fourth depth D₄ (see FIG. 8B) of the bottom 20a of the second diffusion region 20 (D₇=D₁=D₄). The first diffusion layer 51 may be formed in the same process as the first diffusion region 17. Referring to FIGS. 6 and 9, the second diffusion layer 52 is an upper layer of the laminated structure LS1. The second diffusion layer 52 is formed in a surface layer portion of the first diffusion layer 51. In this embodiment, the second diffusion layer 52 is circular in a plan view. The first diffusion layer 51 surrounds lower and lateral sides of the second diffusion layer 52. A p-type impurity concentration of the second diffusion layer 52 is 1.0×10¹⁶ cm⁻³ or more and 1.0×10¹⁸ cm⁻³ or less. The p-type impurity concentration of the second diffusion layer 52 is higher than the p-type impurity concentration of the semiconductor substrate 7. In this embodiment, the p-type impurity concentration of the second diffusion layer 52 is the same as the p-type impurity concentration of the second diffusion region 20.

Referring to FIG. 10, a peripheral edge of the second diffusion layer 52 is located inward of the peripheral edge of the first diffusion layer 51 (the peripheral edge of the laminated structure LS1). A second diameter (width) DL₂ of the second diffusion layer 52 is, for example, 200 μm or more and 950 mm or less. The second diameter DL₂ is larger than the first width W₁ (see FIG. 8B) of the first diffusion region 17 (DL₂>W₁). The second diameter DL₂ is larger than the fourth width W₄ (see FIG. 8B) of the second diffusion region 20 (DL₂>W₄).

Referring to FIG. 10, an eighth depth D₈ of a bottom 52a of the second diffusion layer 52 is, for example, 0.7 μm or more and 3 μm or less. In this embodiment, the eighth depth D₈ is smaller than the seventh depth D₇ (D₈<D₇). The eighth depth D₈ is smaller than the first depth D₁ of the bottom 17a of the first diffusion region 17 (see FIG. 8B) and the fourth depth D₄ of the bottom 20a of the second diffusion region 20 (see FIG. 8B) (D₈<D₁=D₄). The eighth depth D₈ is larger than the third depth D₃ of the bottom 19a of the p-type emitter region 19 (see FIG. 8B) and the sixth depth De of the bottom 22a of the p-type base region 22 (see FIG. 8B) (D₆>D₃=D₆).

In the laminated structure LS1, a first laminated parasitic capacitance (internal parasitic capacitance) C1 is formed between the p-type second diffusion layer 52 and the n-type first diffusion layer 51. A second laminated parasitic capacitance (internal parasitic capacitance) C2 is formed between the n-type first diffusion layer 51 and the p-type semiconductor substrate 7.

In addition, since the first pad 9 is at the same potential as the n-type first diffusion region 17, a parasitic capacitance is formed between the first pad 9 and the p-type semiconductor substrate 7. The first pad 9 faces the first pad region 10 across the insulating layer 23 (faces a facing portion 7a in a surface of the semiconductor substrate 7 that faces the first pad 9), and a parasitic capacitance CP1 is formed.

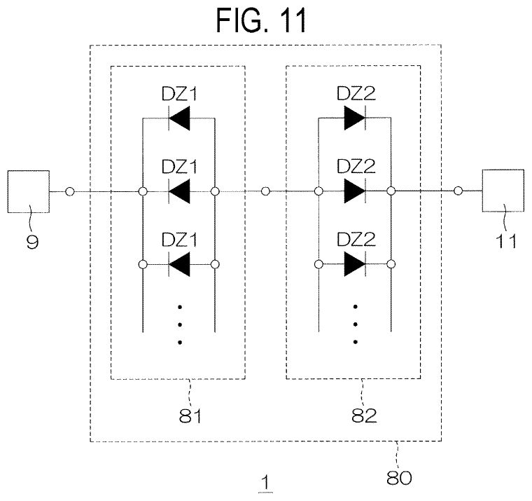

FIG. 11 is an electrical circuit diagram of the semiconductor device 1. The semiconductor device 1 includes the first pad 9, the second pad 11, and a TVS circuit 80. The TVS circuit 80 is formed of a series circuit in which a first parallel circuit 81 and a second parallel circuit 82 are connected in series, and is electrically connected to the first pad 9 and the second pad 11.

The first parallel circuit 81 includes a plurality of first Zener diodes DZ1 connected in parallel to one another. Cathodes of the first Zener diodes DZ1 are connected to the first pad 9. Anodes of the first Zener diodes DZ1 are electrically connected to the second pad 11.

The second parallel circuit 82 includes a plurality of second Zener diodes DZ2 connected in parallel to one another. Anodes of the second Zener diodes DZ2 are electrically connected to the first pad 9. Cathodes of the second Zener diodes DZ2 are electrically connected to the second pad 11.

The semiconductor device 1 is a bidirectional device that can cause a current to flow in both directions of the first pad 9 and the second pad 11. That is, when a voltage equal to or higher than a predetermined threshold voltage is applied between the first pad 9 and the second pad 11 with the first pad 9 being positive, a current flows from the first pad 9 to the second pad 11 via the first Zener diodes DZ1.

On the other hand, when a voltage equal to or higher than a predetermined threshold voltage is applied between the first pad 9 and the second pad 11 with the second pad 11 being positive, a current flows from the second pad 11 to the first pad 9 via the second Zener diodes DZ2.

As described above, in the laminated structure LS1, the first laminated parasitic capacitance C1 is formed between the p-type second diffusion layer 52 and the n-type first diffusion layer 51. Further, the second laminated parasitic capacitance C2 is formed between the n-type first diffusion layer 51 and the p-type semiconductor substrate 7. Furthermore, the first pad 9 faces the first pad region 10 with the insulating layer 23 interposed therebetween, and the parasitic capacitance (first parasitic capacitance and second parasitic capacitance) CP1 is formed between the first pad 9 and the insulating layer 23. In this embodiment, since a first trench 451 is not formed in the first main surface 3, a total thickness of the insulating layer 23 coincides with the thickness T230 of the upper portion 230. Therefore, in this embodiment, the parasitic capacitance (first parasitic capacitance) between the first pad 9 and the upper portion 230 and the parasitic capacitance (second parasitic capacitance) between the first pad 9 and the insulating layer 23 are both parasitic capacitance CP1.

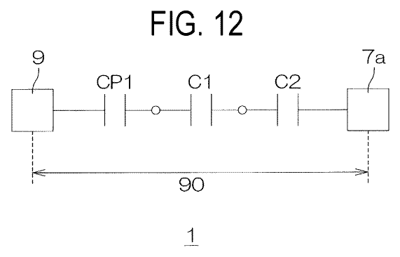

FIG. 12 is an electric circuit diagram showing parasitic capacitances around the first pad 9 (a portion between the first pad 9 and the facing portion 7a of the semiconductor substrate 7 that faces the first pad 9).

The semiconductor device 1 includes the first pad 9, the facing portion 7a (see FIGS. 9 and 10) of the semiconductor substrate 7 that faces the first pad 9, and a first pad parasitic capacitance circuit 90. The first pad parasitic capacitance circuit 90 forms a series circuit formed of the first laminated parasitic capacitance C1, the second laminated parasitic capacitance C2, and the parasitic capacitance CP1. A combined capacitance CS1 around the first pad 9 is expressed by the following formula (1).

$$C S 1 = \frac{C 1 \times C 2}{C P 1 \times C 1 + C P 1 \times C 2 + C 1 \times C 2} \times CP 1 \qquad ( 1 )$$

In contrast, a case in which the laminated structure LS1 (laminated parasitic capacitance former 50) is removed is reviewed. In this case, a combined capacitance CS1* around the first pad 9 is equal to the parasitic capacitance CP1. The combined capacitance CS1 is less than the combined capacitance CS1*. Therefore, by forming the laminated structure LS1 on the first main surface 3, the parasitic capacitance around the first pad 9 can be reduced.

As described above, according to the first embodiment, the laminated structure LS1 having the first diffusion layer 51 and the second diffusion layer 52 is formed on the first main surface 3. The first laminated parasitic capacitance C1 is formed between the p-type second diffusion layer 52 and the n-type first diffusion layer 51, and the second laminated parasitic capacitance C2 is formed between the n-type first diffusion layer 51 and the semiconductor substrate 7 of the first conductivity type. The first pad 9 faces the first pad region 10 with the insulating layer 23 interposed therebetween, and the parasitic capacitance CP1 is formed between the first pad 9 and the insulating layer 23. The parasitic capacitance CP1 forms a series circuit with the first laminated parasitic capacitance C1 and the second laminated parasitic capacitance C2. Thus, it is possible to reduce the parasitic capacitance around the first pad 9 compared to the case where the laminated structure LS1 is not formed on the first main surface 3.

In addition, the seventh depth D7 of the bottom 51a of the first diffusion layer 51 is the same as the first depth D1 of the bottom 17a of the first diffusion region 17. Therefore, the first diffusion layer 51 and the first diffusion region 17 can be formed in the same process. Compared to the case where the first diffusion layer 51 and the first diffusion region 17 are formed separately, the number of processes can be reduced.

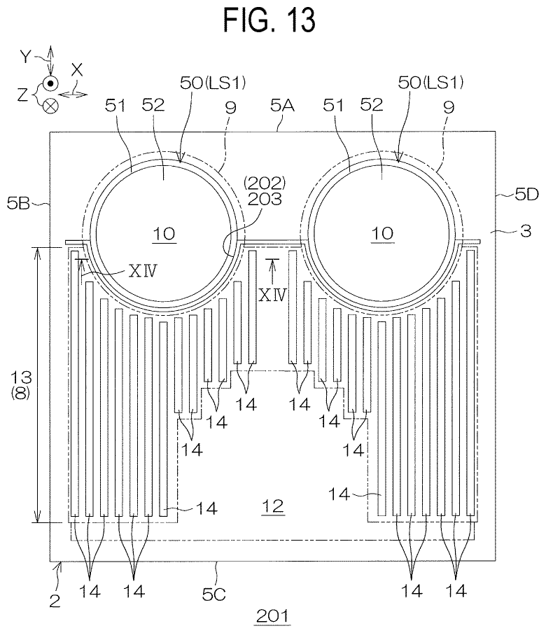

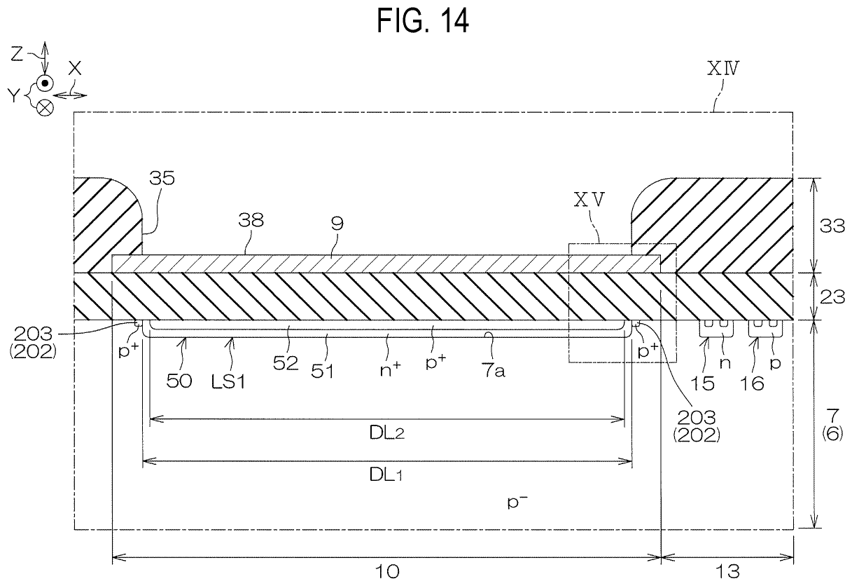

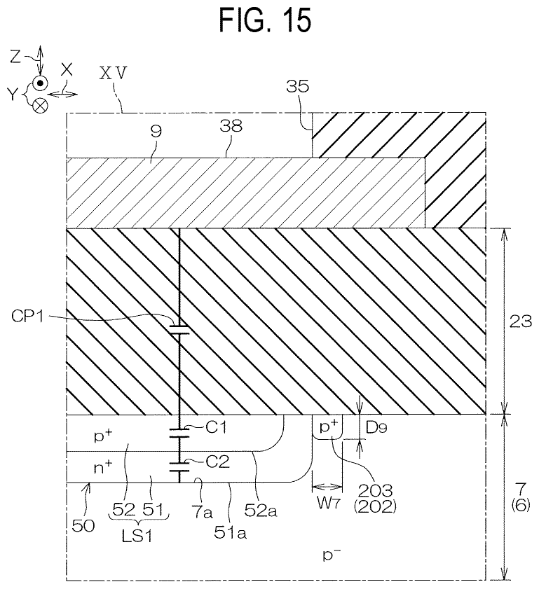

FIG. 13 is a schematic plan view of a chip 2 included in a semiconductor device 201 according to a second embodiment of the present disclosure, and a view corresponding to FIG. 6. FIG. 14 is a cross-sectional view taken along line XIV-XIV in FIG. 13. FIG. 15 is an enlarged view of a portion surrounded by one-dot chain line XV in FIG. 14. In FIGS. 13 to 15, the configurations that are the same as those described so far are designated by like reference symbols, and descriptions thereof will be omitted.

The semiconductor device 201 differs from the semiconductor device 1 in that an isolator 202 that isolates the first pad region 10 from the thyristor region 13 is provided on the first main surface 3.

Referring to FIG. 13, the isolator 202 is formed in a stripe shape so as to cross between the n-type first diffusion layer 51 of the laminated structure LS1 and the diffusion regions 17 and 20 of the thyristor structure 14. In this embodiment, the isolator 202 is formed linearly along the boundary between the first pad region 10 and the thyristor region 13 on the first main surface 3. The isolators 202 corresponding to the two first pad regions 10 are connected to each other.

In this embodiment, the isolator 202 is formed of a p-type high concentration region 203. A p-type impurity concentration of the p-type high concentration region 203 is 1.0×10¹⁹ cm⁻³ or more and 1.0×10²⁰ cm⁻³ or less. The p-type impurity concentration of the p-type high concentration region 203 is higher than the p-type impurity concentration of the semiconductor substrate 7. The p-type impurity concentration of the p-type high concentration region 203 is higher than the p-type impurity concentration of the second diffusion region 20 (see FIG. 8A). The p-type impurity concentration of the p-type high concentration region 203 is equal to the p-type impurity concentrations of the p-type emitter region 19 (see FIG. 8A) and the p-type base region 22 (see FIG. 8A).

Referring to FIG. 15, the p-type high concentration region 203 has a seventh width W₇. The seventh width W₇ is, for example, 0.5 μm or more and 3 μm or less. The seventh width W₇ may be equal to the third width W₃ (see FIG. 8B) of the p-type emitter region 19 and the sixth width W₆ (see FIG. 8B) of the p-type base region 22 (W₇=W₃=W₆). The seventh width W₇ may be wider than the third width W₃ and the sixth width W₆ (W₇>W₃=W₆), or narrower than the third width W₃ and the sixth width W₆ (W₇<W₃=W₆).

A ninth depth D₉ of the p-type high concentration region 203 is, for example, 0.5 μm or more and 2 μm or less. In this embodiment, the ninth depth Do is equal to the third depth D₃ (see FIG. 8B) of the p-type emitter region 19 and the sixth depth D₆ (see FIG. 8B) of the p-type base region 22 (D₉=D₃=D₆).

Since the p-type high concentration region 203 is formed to cross between the n-type first diffusion layer 51 and the n-type first diffusion region 17, it is possible to prevent interference between a depletion layer extending from the first diffusion region 17 and a depletion layer extending from the first diffusion layer 51.

The semiconductor device 201 according to the second embodiment of the present disclosure provides the same operative effects as those described in relation to the first embodiment.

In addition, according to the semiconductor device 201, the p-type high concentration region 203 can prevent interference between the depletion layer extending from the first diffusion region 17 and the depletion layer extending from the first diffusion layer 51. Therefore, the parasitic capacitance in the first pad region 10 (the parasitic capacitance in the laminated structure LS1) can be kept even higher, thereby reducing the parasitic capacitance around the first pad 9.

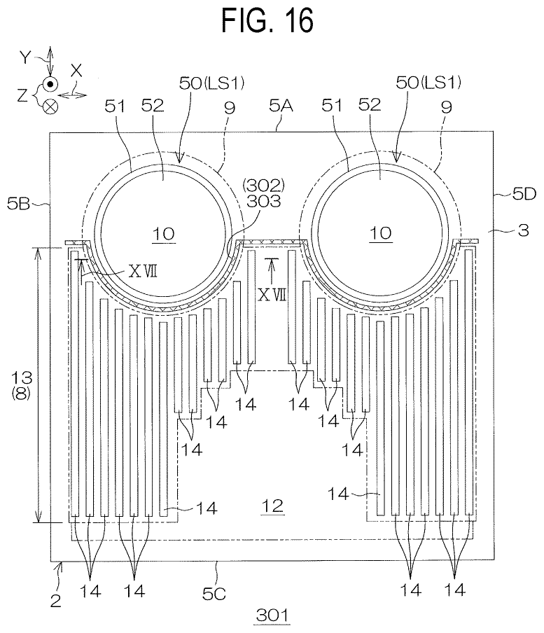

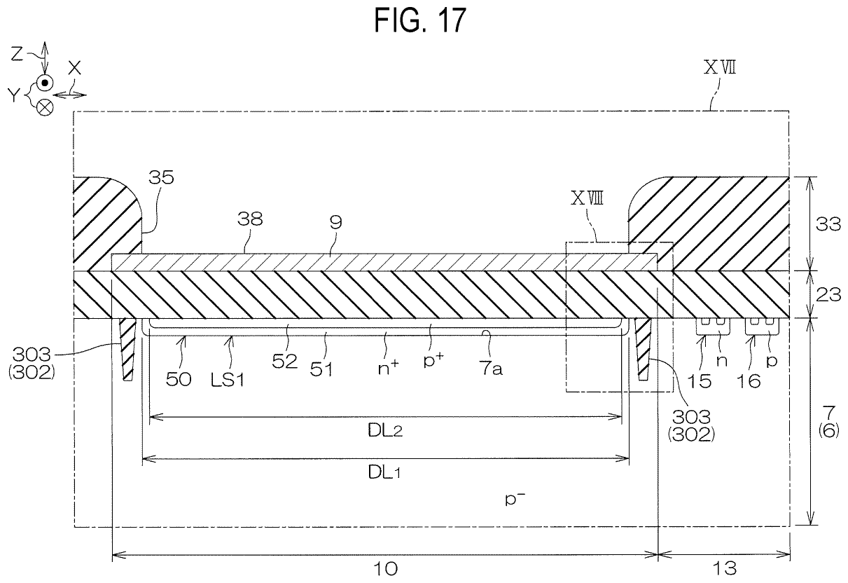

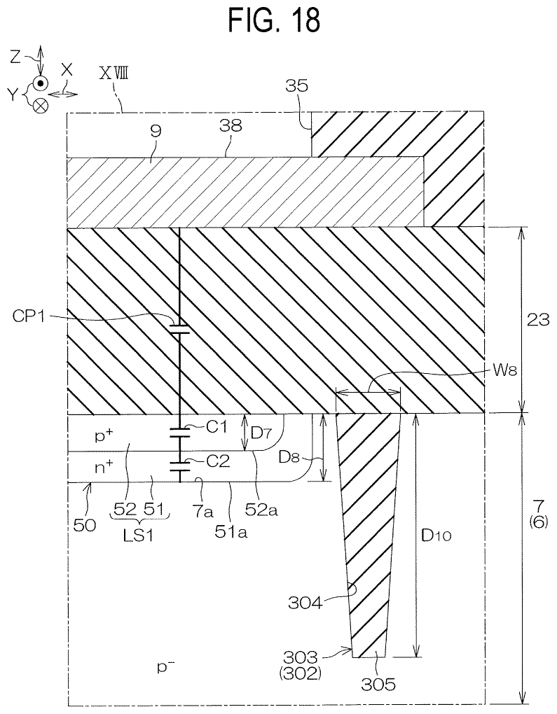

FIG. 16 is a schematic plan view of a diode chip included in a semiconductor device 301 according to a third embodiment of the present disclosure, and a view corresponding to FIG. 6. FIG. 17 is a cross-sectional view taken along line XVII-XVII in FIG. 16. FIG. 18 is an enlarged view of a portion surrounded by one-dot chain line XVIII in FIG. 17. In FIGS. 16 to 18, the configurations that are the same as those described so far are designated by like reference symbols, and descriptions thereof will be omitted.

The semiconductor device 301 differs from the semiconductor device 1 in that an isolator 302 that isolates the first pad region 10 from the thyristor region 13 is provided on the first main surface 3.

Referring to FIG. 16, the isolator 302 is formed in a stripe shape to cross between the n-type first diffusion layer 51 of the laminated structure LS1 and the diffusion regions 17 and 20 of the thyristor structure 14. In this embodiment, the isolator 302 is formed linearly along a boundary between the first pad region 10 and the thyristor region 13 on the first main surface 3. The isolators 302 corresponding to the two first pad regions 10 are connected to each other.

In this embodiment, the isolator 302 includes an insulating trench structure 303. The insulating trench structure 303 includes an insulating trench 304 and an insulator 305 formed on an inner surface of the insulating trench 304. The insulating trench structure 303 insulates a surface layer portion of the first pad region 10 from a surface layer portion of the thyristor region 13.

Referring to FIG. 18, the insulating trench 304 is formed in the first main surface 3. The insulating trench 304 has a tenth depth D₁₀. The tenth depth D₁₀ may be 1 μm or more and 50 μm or less. The tenth depth D₁₀ may be 1 μm or more and 5 μm or less, 5 μm or more and 10 μm or less, 10 μm or more and 15 μm or less, 15 μm or more and 20 μm or less, 20 μm or more and 25 μm or less, 25 μm or more and 30 μm or less, 30 μm or more and 40 μm or less, or 40 μm or more and 50 μm or less. The tenth depth D₁₀ may be larger than the depths of the diffusion regions 17 and 20 of the thyristor structure 14 (the first depth D₁ (see FIG. 8B) and the fourth depth D₄ (see FIG. 8B)). The insulating trench 304 may be formed in a tapered shape in which a width decreases toward a bottom surface described below in a cross-sectional view. The tenth depth D₁₀ of the insulating trench 304 may be 3 μm or more and 10 μm or less.

The insulator 305 may include at least one of a silicon oxide film, a silicon nitride film, or a silicon oxynitride film. In this embodiment, the insulator 305 includes a silicon oxide film.

Since the insulating trench structure 303 insulates the surface layer portion of the first pad region 10 from the surface layer portion of the thyristor region 13, the presence of the insulating trench structure 303 hinders a current flow between the first pad region 10 and the thyristor region 13, and a current path between the first pad region 10 and the thyristor region 13 detours in the vertical direction Z.

The semiconductor device 301 according to the third embodiment of the present disclosure provides the same operative effects as those described in relation to the first embodiment.

Further, according to the semiconductor device 301, since the insulating trench structure 303 hinders a current flow between the first pad region 10 and the thyristor region 13, the parasitic capacitance in the first pad region 10 (the parasitic capacitance in the laminated structure LS1) can be kept even higher, thereby reducing the parasitic capacitance around the first pad 9.

Furthermore, since the insulating trench structure 303 is formed deep, it is possible to further hinder a current flow between the laminated structure LS1 and the first diffusion region 17. Therefore, the parasitic capacitance in the first pad region 10 (the parasitic capacitance in the laminated structure LS1) can be kept even higher, thereby further reducing the parasitic capacitance around the first pad 9.

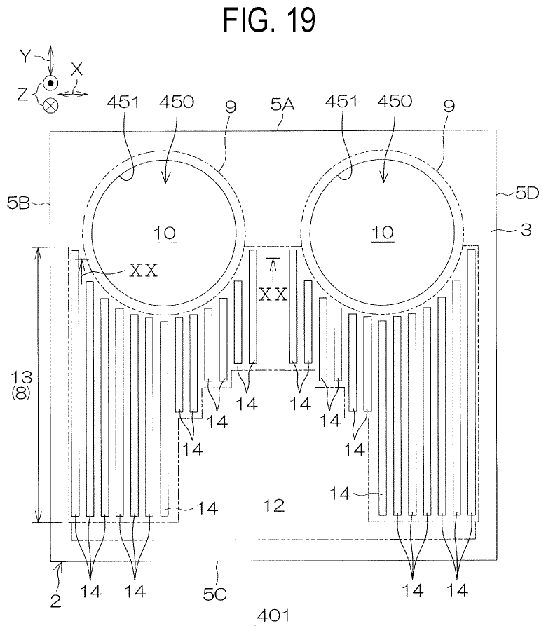

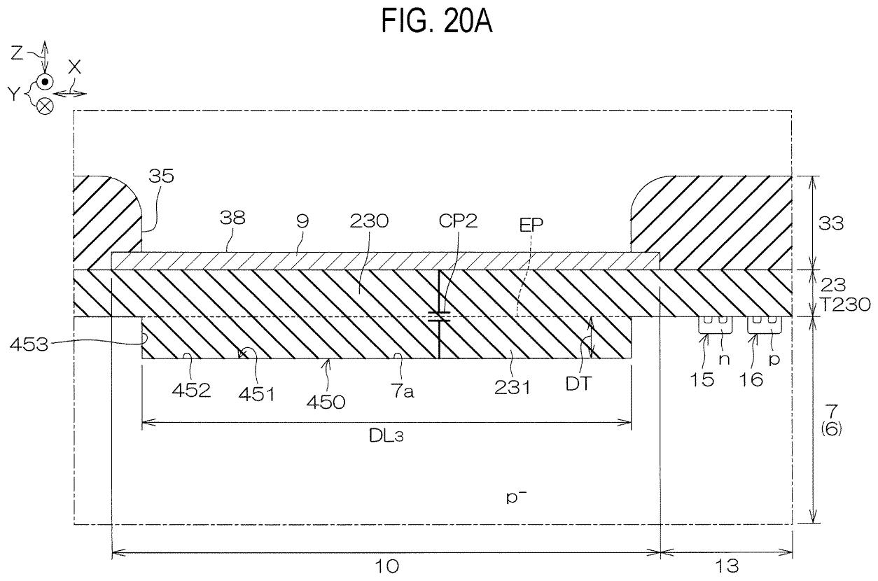

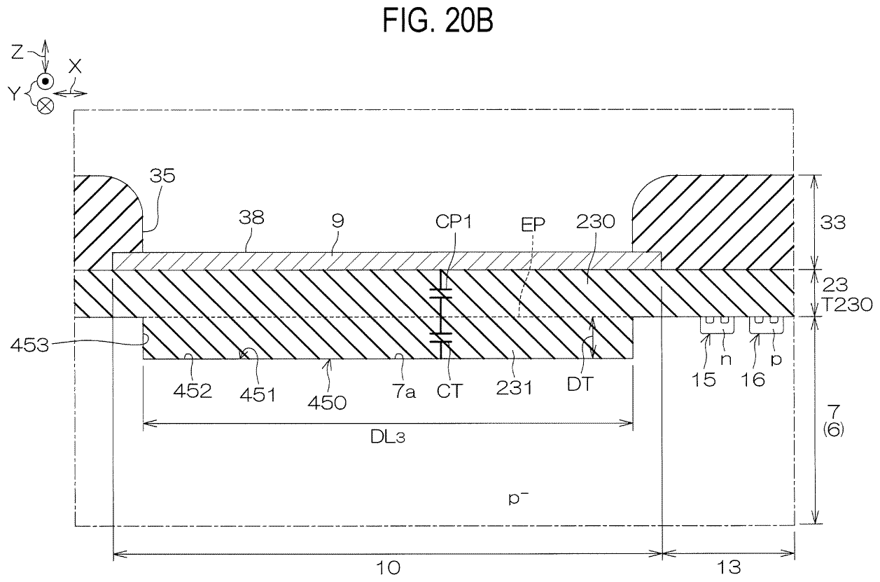

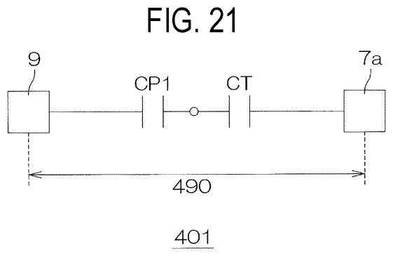

FIG. 19 is a schematic plan view of a chip 2 included in a semiconductor device 401 according to a fourth embodiment of the present disclosure, and a view corresponding to FIG. 6. FIGS. 20A and 20B are cross-sectional views taken along line XX-XX in FIG. 19. FIG. 21 is an electric circuit diagram showing parasitic capacitances around the first pad 9 according to the fourth embodiment (a portion between the first pad 9 and the facing portion 7a of the semiconductor substrate 7 that faces the first pad 9). In FIGS. 19 to 21, the configurations that are the same as those described so far are designated by like reference symbols, and descriptions thereof will be omitted.

The semiconductor device 401 includes a trench parasitic capacitance former (internal parasitic capacitance former) 450 formed in the first pad region 10. The trench parasitic capacitance former 450 includes a first trench 451 formed in the first main surface 3 and an intra-trench insulating layer 231 embedded in the first trench 451. The intra-trench insulating layer 231 is a part of the insulating layer 23. The semiconductor device 401 differs from the semiconductor device 1 in that the semiconductor device 401 includes the trench parasitic capacitance former 450 instead of the laminated parasitic capacitance former 50.

The first trench 451 of the trench parasitic capacitance former 450 defines an inner surface (side surface 453 and bottom surface 452 shown in FIGS. 20A and 20B) of the trench parasitic capacitance former 450. The first trench 451 is cylindrical in this embodiment.

The side surface 453 of the first trench 451 is a cylindrical surface. In this embodiment, the side surface 453 is perpendicular to the first main surface 3 (extends in the vertical direction Z). The side surface 453 of the first trench 451 is located inward of the peripheral edge of the first pad 9 in a plan view. A peripheral edge portion of the first trench 451 is aligned with the peripheral edge of the first electrode surface 38 in a plan view. The side surface 453 may be a tapered surface having a diameter decreasing toward the second main surface 4.

Referring to FIGS. 20A and 20B, the side surface 453 of the first trench 451 has a third diameter (width) DL₃. The third diameter DL₃ is, for example, 250 μm or more and 1 mm or less. The third diameter DL₃ is larger than the first width W₁ (see FIG. 8B) of the first diffusion region 17 (DL₃>W₁). The third diameter DL₃ is larger than the fourth width W₄ (see FIG. 8B) of the second diffusion region 20 (DL₃>W₄).

The bottom surface 452 of the first trench 451 may have a portion (a flat surface) that extends flat. Specifically, the flat portion (flat surface) of the bottom surface 452 of the first trench 451 may extend substantially parallel to the first main surface 3. Of course, the bottom surface 452 of the first trench 451 may be curved in an arc shape toward the second main surface 4.

The first trench 451 has a trench depth DT in the vertical direction Z. The trench depth DT may be 3 μm or more and 30 μm or less. The trench depth DT may have a value belonging to any one of ranges of 3 μm or more and 5 μm or less, 5 μm or more and 10 μm or less, 10 μm or more and 15 μm or less, 15 μm or more and 20 μm or less, 20 μm or more and 25 μm or less, and 25 μm or more and 30 μm or less. Specifically, the trench depth DT may be 5 μm or more and 15 μm or less.

In this embodiment, the trench depth DT is larger than the first depth D₁ (see FIG. 8B) of the bottom 17a of the first diffusion region 17 and the fourth depth D₄ (see FIG. 8B) of the bottom 20a of the second diffusion region 20 (DT>D₁=D₄). In this embodiment, the trench depth DT may be smaller than the third diameter DL₃ of the side surface 453.

The intra-trench insulating layer 231 of the trench parasitic capacitance former 450 is located below an extension surface EP of the first main surface 3 (hereinafter simply referred to as an “extension surface EP”) in the surface layer portion of the first main surface 3 (a formation region of the first trench 451). In this specification, the extension surface EP is an imaginary surface located on the same plane as the first main surface 3 above the first trench 451. The intra-trench insulating layer 231 is a part of the insulating layer 23. In other words, the insulating layer 23 includes the upper portion 230 located above the first main surface 3 and the extension surface EP, and the intra-trench insulating layer 231. In this embodiment, a thickness of the intra-trench insulating layer 231 is equal to the trench depth DT of the first trench 451.

In this embodiment, the intra-trench insulating layer 231 has a cylindrical shape. The intra-trench insulating layer 231 may include at least one of a silicon oxide film, a silicon nitride film, or a silicon oxynitride film. In this embodiment, the intra-trench insulating layer 231 includes a silicon oxide film.

In this embodiment, the intra-trench insulating layer 231 overlaps with the first pad 9 in a plan view. More specifically, the intra-trench insulating layer 231 overlaps with the first electrode surface 38 in a plan view.

The first pad 9 faces the first pad region 10 with the insulating layer 23 (the upper portion 230 and the intra-trench insulating layer 231) interposed therebetween. The first pad 9 forms a parasitic capacitance (third parasitic capacitance) CP2 (see FIG. 20A) between the first pad 9 and the facing portion 7a of the semiconductor substrate 7 that faces the first pad 9. In this embodiment, a total thickness of the insulating layer 23 is a sum of the thickness T230 of the upper portion 230 and the trench depth DT. Since a parasitic capacitance is inversely proportional to a distance between electrodes, the parasitic capacitance CP2 between the first pad 9 and the insulating layer 23 is reduced compared to a case where the first trench 451 is not formed in the first main surface 3 (compared to the first embodiment). Therefore, by forming the first trench 451 in the first main surface 3 and embedding the trench insulating layer 231 in the first trench 451, the parasitic capacitance around the first pad 9 can be reduced. In this embodiment, the parasitic capacitance CP2 is a parasitic capacitance between the first pad 9 and the facing portion 7a formed on the bottom surface 452.

As described above, according to the fourth embodiment, the trench parasitic capacitance former 450 is formed on the first main surface 3 to face the first pad 9 with the insulating layer interposed therebetween. A distance between the first pad 9 and the facing portion 7a can be kept larger than when the first trench 451 is not formed on the first main surface 3. Since a parasitic capacitance is inversely proportional to a distance between electrodes, by keeping a distance between the first pad 9 and the facing portion 7a large, it is possible to reduce the parasitic capacitance around the first pad 9 compared to a case where the trench parasitic capacitance former 450 is not formed on the first main surface 3.

Referring to FIG. 20B, in another point of view, the intra-trench insulating layer 231 forms a parasitic capacitance CP1 (see FIG. 20B) between the semiconductor substrate 7 and the extension surface EP. Further, the trench parasitic capacitance former 450 forms a trench parasitic capacitance CT (internal parasitic capacitance) (see FIG. 20B) between the semiconductor substrate 7 and the extension surface EP. In this case, the parasitic capacitance CP1 forms a series circuit with the trench parasitic capacitance CT.

Referring to FIG. 21, the semiconductor device 401 includes the first pad 9, the facing portion 7a (see FIG. 20B) of the semiconductor substrate 7 that faces the first pad 9, and a first pad parasitic capacitance circuit 490. The first pad parasitic capacitance circuit 490 forms a series circuit formed of the trench parasitic capacitance CT and the parasitic capacitance CP1. A combined capacitance CS2 around the first pad 9 is expressed by the following equation (2).

$$CS 2 = \frac{C T}{CP 1 + CT} \times CP 1 \qquad ( 2 )$$

In contrast, a case in which the trench parasitic capacitance former 450 is removed is reviewed. In this case, a combined capacitance CS2* is equal to the parasitic capacitance CP1. The combined capacitance CS2 is less than the combined capacitance CS2*. Therefore, by forming the trench parasitic capacitance former 450 on the first main surface 3, the parasitic capacitance around the first pad 9 can be reduced.

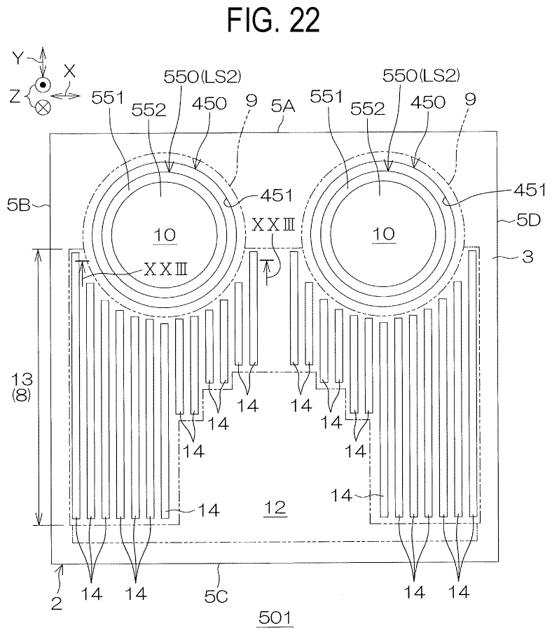

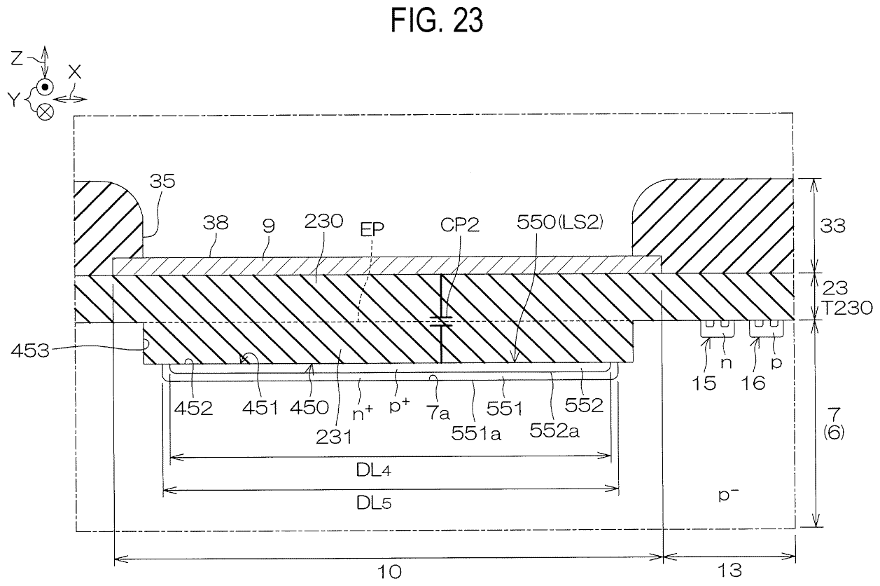

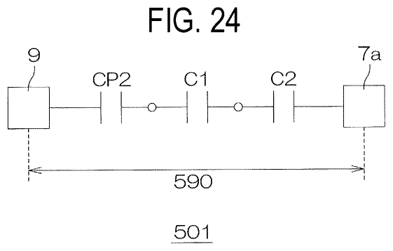

FIG. 22 is a schematic plan view of a chip 2 included in a semiconductor device 501 according to a fifth embodiment of the present disclosure, and a view corresponding to FIG. 6. FIG. 23 is a cross-sectional view taken along line XXIII-XXIII in FIG. 22. FIG. 24 is an electric circuit diagram showing parasitic capacitances around the first pad 9 according to the fifth embodiment. In FIGS. 22 to 24, the configurations that are the same as those described so far are designated by like reference symbols, and descriptions thereof will be omitted.

The semiconductor device 501 includes a laminated parasitic capacitance former (internal parasitic capacitance former) 550 in addition to the trench parasitic capacitance former 450. The semiconductor device 501 differs from the semiconductor device 401 according to the fourth embodiment in that it includes the laminated parasitic capacitance former 550.

The laminated parasitic capacitance former 550 has a laminated structure LS2 of an n-type first diffusion layer 551 and a p-type second diffusion layer 552. The laminated structure LS2 (laminated parasitic capacitance former 550) forms a parasitic capacitance between the semiconductor substrate 7 and the bottom surface 452 of the first trench 451.

In this embodiment, the laminated structure LS2 is circular in a plan view. In a plan view, a peripheral edge of the laminated structure LS2 is located inward of and spaced apart from a peripheral edge of the bottom surface 452 of the first trench 451. In this embodiment, the peripheral edge portion of the laminated structure LS2 is located inward of the peripheral edge of the first electrode surface 38 in a plan view.

The laminated structure LS2 differs from the laminated structure LS1 in that the laminated structure LS2 is formed on the bottom surface 452 of the first trench 451 and that a peripheral edge portion of the laminated structure LS2 is located inward of the peripheral edge of the first electrode surface 38 in a plan view. In other respects, the laminated structure LS2 is common to the laminated structure LS1.

The first diffusion layer 551 is a lower layer of the laminated structure LS2. A peripheral edge of the first diffusion layer 551 is the peripheral edge of the laminated structure LS2. An n-type impurity concentration of the first diffusion layer 551 is 1.0×10¹⁶ cm⁻³ or more and 1.0×10¹⁸ cm⁻³ or less. The n-type impurity concentration of the first diffusion layer 551 is higher than the p-type impurity concentration of the semiconductor substrate 7. In this embodiment, the n-type impurity concentration of the first diffusion layer 551 is the same as the n-type impurity concentration of the first diffusion region 17.

A fourth diameter (width) DL₄ of the first diffusion layer 551 is smaller than the third diameter DL₃ of the first trench 451 (DL₄<DL₃). The fourth diameter DL₄ is larger than the first width W₁ (see FIG. 8B) of the first diffusion region 17 (DL₄>W₁). The fourth diameter DL₄ is larger than the fourth width W₄ (see FIG. 8B) of the second diffusion region 20 (DL₄>W₄). A depth of a bottom 551a of the first diffusion layer 551 is the same as the seventh depth D₇ (see FIG. 8B) of the bottom 51a of the first diffusion layer 51.

The second diffusion layer 552 is an upper layer of the laminated structure LS2. Lower and lateral sides of the second diffusion layer 552 are surrounded by the first diffusion layer 551. The p-type impurity concentration of the second diffusion layer 552 is 1.0×10¹⁶ cm⁻³ or more and 1.0×10¹⁸ cm⁻³ or less. The p-type impurity concentration of the second diffusion layer 552 is higher than the p-type impurity concentration of the semiconductor substrate 7. In this embodiment, the p-type impurity concentration of the second diffusion layer 552 is the same as the p-type impurity concentration of the second diffusion region 20.

A peripheral edge of the second diffusion layer 552 is located inward of the peripheral edge of the first diffusion layer 551 (the peripheral edge of the laminated structure LS2). A fifth diameter (width) DL₅ of the second diffusion layer 552 is smaller than the fourth diameter (width) DL₄ of the first diffusion layer 551 (DL₅<DL₄). The fifth diameter DL₅ of the second diffusion layer 552 is smaller than the third diameter DL₃ of the first trench 451 (DL₅<DL₃). The fifth diameter DL₅ is larger than the first width W₁ of the first diffusion region 17 (see FIG. 8B) (DL₅>W₁). The fifth diameter DL₅ is larger than the fourth width W₄ of the second diffusion region 20 (see FIG. 8B) (DL₅>W₄). A depth of the bottom 552a of the second diffusion layer 552 is the same as the eighth depth D₈ of the bottom 51a of the first diffusion layer 51 (see FIG. 8B).

In the laminated structure LS2, a first laminated parasitic capacitance C1 is formed between the p-type second diffusion layer 552 and the n-type first diffusion layer 551. Further, a second laminated parasitic capacitance C2 is formed between the n-type first diffusion layer 551 and the p-type semiconductor substrate 7. Furthermore, the first pad 9 faces the first pad region 10 across the insulating layer 23 (faces the facing portion 7a on the surface of the semiconductor substrate 7 that faces the first pad 9), thereby forming a parasitic capacitance CP2.

Referring to FIG. 24, the semiconductor device 501 includes the first pad 9, the facing portion 7a (see FIG. 23) of the semiconductor substrate 7 facing the first pad 9, and a first pad parasitic capacitance circuit 590. The first pad parasitic capacitance circuit 590 forms a series circuit formed of the first laminated parasitic capacitance C1, the second laminated parasitic capacitance C2, and the parasitic capacitance CP2. A combined capacitance CS3 around the first pad 9 is expressed by the following equation (3).

$$CS 3 = \frac{C 1 \times C 2}{C P 2 \times C 1 + C P 2 \times C 2 + C 1 \times C 2} \times CP 2 \qquad ( 3 )$$

In contrast, a case in which the laminated structure LS2 (laminated parasitic capacitance former 550) is removed from the bottom surface 452 of the first trench 451 (i.e., the case of the fourth embodiment) is reviewed. In this case, a combined capacitance CS3* is equal to the parasitic capacitance CP2. The combined capacitance CS3 is less than the combined capacitance CS3*. Therefore, by forming the laminated structure LS2 on the first main surface 3, the parasitic capacitance around the first pad 9 can be further reduced.

The semiconductor device 501 according to the fifth embodiment of the present disclosure provides the same operative effects as those described in relation to the fourth embodiment.

Further, according to the semiconductor device 501, in the first pad region 10, the laminated structure LS2 having the first diffusion layer 551 and the second diffusion layer 552 is formed on the bottom surface 452 of the first trench 451. The first laminated parasitic capacitance C1 is formed between the p-type second diffusion layer 552 and the n-type first diffusion layer 551, and the second laminated parasitic capacitance C2 is formed between the n-type first diffusion layer 551 and the semiconductor substrate 7 of the first conductivity type. The first pad 9 faces the first pad region 10 with the insulating layer 23 interposed therebetween, and forms the parasitic capacitance CP2. The parasitic capacitance CP2 forms a series circuit with the first laminated parasitic capacitance C1 and the second laminated parasitic capacitance C2. Thus, it is possible to reduce the parasitic capacitance around the first pad 9 compared to the fourth embodiment.

Furthermore, the semiconductor device 501 according to the fifth embodiment of the present disclosure provides the same operative effects as those described in relation to the first embodiment.

Moreover, with the semiconductor device 501 according to the fifth embodiment of the present disclosure, in the first pad region 10, the trench parasitic capacitance former 450 is formed in the first main surface 3. Compared to a case where the first trench 451 is not formed in the first main surface 3, a distance between the first pad 9 and the facing portion 7a can be kept large. Since a parasitic capacitance is inversely proportional to a distance between electrodes, by keeping the distance between the first pad 9 and the facing portion 7a large, it is possible to reduce the parasitic capacitance around the first pad 9 compared to the first embodiment.

While several embodiments of the present disclosure have been described above, the present disclosure may be embodied in other forms.

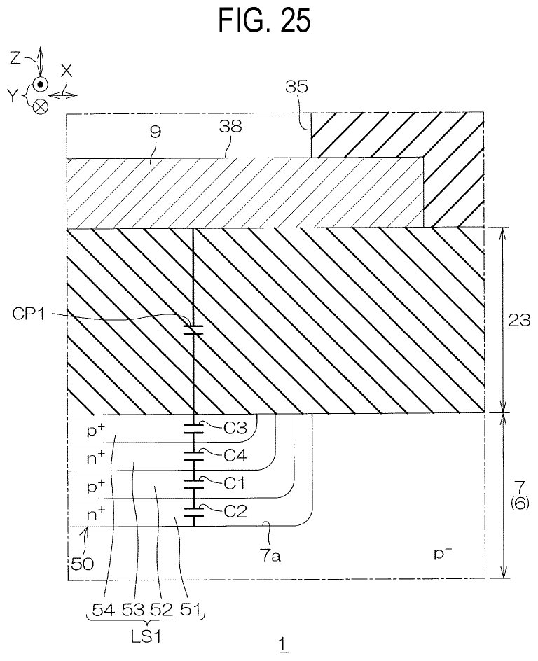

As shown in FIG. 25, in the semiconductor device 1 according to the first embodiment, the laminated structure LS1 of the laminated parasitic capacitance former 50 may be a multi-layer structure having more than two layers. In the example of FIG. 25, the laminated structure LS1 is a four-layer structure. In the example of FIG. 25, the laminated structure LS1 includes a first diffusion layer 51, a second diffusion layer 52, an n-type third diffusion layer 53 formed in a surface layer portion of the second diffusion layer 52, and a p-type fourth diffusion layer 54 formed in a surface layer portion of the third diffusion layer 53.

The third diffusion layer 53 is an intermediate layer of the laminated structure LS1. In this embodiment, the third diffusion layer 53 is circular in a plan view. The second diffusion layer 52 surrounds lower and lateral sides of the third diffusion layer 53. An n-type impurity concentration of the third diffusion layer 53 is 1.0×10¹⁶ cm⁻³ or more and 1.0×10¹⁸ cm⁻³ or less. The n-type impurity concentration of the third diffusion layer 53 may be the same as the n-type impurity concentration of the first diffusion layer 51. The n-type impurity concentration of the third diffusion layer 53 may be higher than the n-type impurity concentration of the first diffusion layer 51, or may be lower than the n-type impurity concentration of the first diffusion layer 51.

The fourth diffusion layer 54 is the uppermost layer of the laminated structure LS1. In this embodiment, the fourth diffusion layer 54 is circular in a plan view. The third diffusion layer 53 surrounds lower and lateral sides of the fourth diffusion layer 54. A p-type impurity concentration of the fourth diffusion layer 54 is 1.0×10¹⁶ cm⁻³ or more and 1.0×10¹⁸ cm⁻³ or less. The p-type impurity concentration of the fourth diffusion layer 54 may be higher than the p-type impurity concentration of the second diffusion layer 52, or may be lower than the p-type impurity concentration of the second diffusion layer 52.

In the example of FIG. 25, a first laminated parasitic capacitance C1 is formed between the p-type second diffusion layer 52 and the n-type first diffusion layer 51. A second laminated parasitic capacitance C2 is formed between the n-type first diffusion layer 51 and the p-type semiconductor substrate 7. A third laminated parasitic capacitance (internal parasitic capacitance) C3 is formed between the p-type fourth diffusion layer 54 and the n-type third diffusion layer 53. A fourth laminated parasitic capacitance (internal parasitic capacitance) C4 is formed between the n-type third diffusion layer 53 and the p-type second diffusion layer 52. The first pad 9 faces the first pad region 10 with the insulating layer 23 interposed therebetween, and forms a parasitic capacitance CP1.

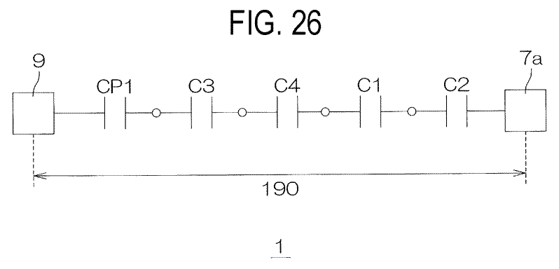

As shown in FIG. 26, the semiconductor device 1 includes the first pad 9, the facing portion 7a (see FIG. 25) of the semiconductor substrate 7 that faces the first pad 9, and a first pad parasitic capacitance circuit 190. The first pad parasitic capacitance circuit 190 forms a series circuit formed of the third laminated parasitic capacitance C3, the fourth laminated parasitic capacitance C4, the first laminated parasitic capacitance C1, the second laminated parasitic capacitance C2, and the parasitic capacitance CP1. A combined capacitance CS4 around the first pad 9 is expressed by the following equation (4).

$$C S 4 = \frac{C 1 \times C 2 \times C 3 \times C 4}{\begin{matrix}( C P 1 \times C 1 \times C 2 \times C 3 + C P 1 \times C 1 \times C 2 \times C 4 + CP 1 C 1 \times \\ C 3 \times C 4 + C P 1 \times C 2 \times C 3 \times C 4 + C 1 \times C 2 \times C 3 \times C 4 )\end{matrix}} \times CP 1 \qquad ( 4 )$$

Therefore, by forming the laminated structure LS1 as a multi-layer structure of three or more layers, it is possible to further reduce the parasitic capacitance around the first pad 9.

The modification (first modification) shown in FIGS. 25 and 26 may be applied to the laminated parasitic capacitance former 550 (laminated structure LS2) of the fourth and fifth embodiments.

The laminated structures LS1 and LS2 are not limited to the four-layer laminated structures. The laminated structures LS1 and LS2 may be three-layer structures without having the fourth diffusion layer 54. The laminated structures LS1 and LS2 may further include an n-type fifth diffusion layer formed on a surface layer portion of the fourth diffusion layer 54, and may have five or more layers.

The modification (first modification) shown in FIGS. 25 and 26 may be combined with any of the embodiments (including the modifications) other than the first, fourth and fifth embodiments.

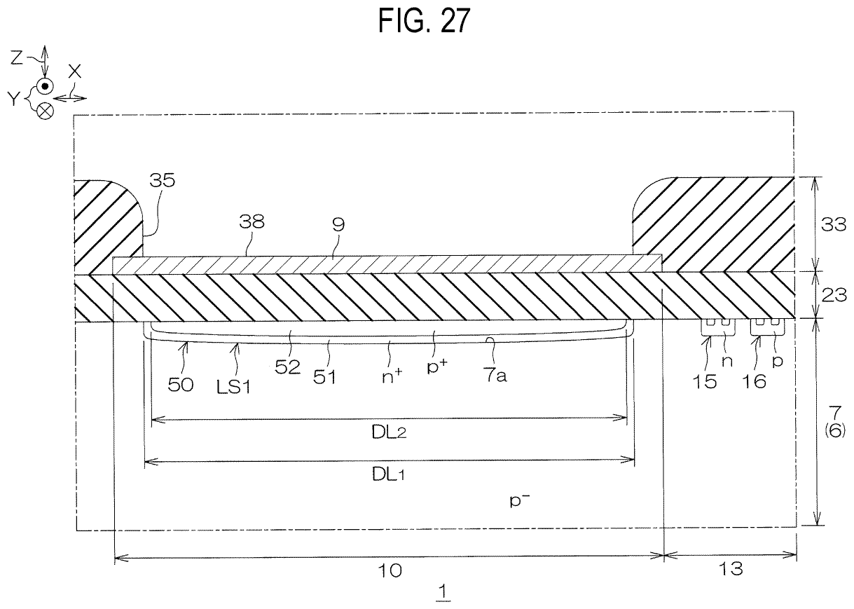

In addition, as shown in FIG. 27, in the semiconductor device 1 according to the first embodiment, the bottom of the first diffusion layer 51 and the bottom of the second diffusion layer 52 may not be flat but may have a curved surface that is convex downward. The bottom of the first diffusion layer 51 and the bottom of the second diffusion layer 52 may have a spherical surface that is convex downward. Centers of the bottom of the first diffusion layer 51 and the bottom of the second diffusion layer 52 may be the deepest portions.

In this case, a contact area between the first diffusion layer 51 and the second diffusion layer 52 can be increased compared to a case where the bottom of the first diffusion layer 51 and the bottom of the second diffusion layer 52 are flat. Thus, it is possible to increase the parasitic capacitance of the laminated structure LS1 and to further reduce the parasitic capacitance around the first pad 9.

The modification (second modification) shown in FIG. 27 may be combined with any of the embodiments (including the modifications) other than the first embodiment.

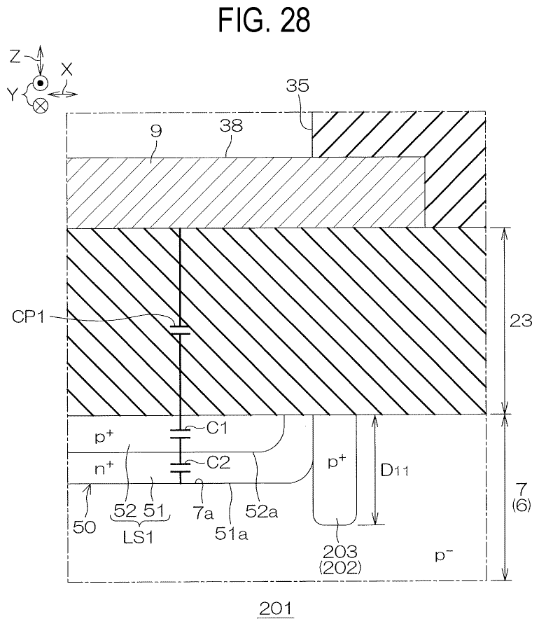

As shown in FIG. 28, a depth (eleventh depth D₁₁) of the p-type high concentration region 203 may be larger than the third depth D₃ (see FIG. 8B) of the p-type emitter region 19 and the sixth depth D₆ (see FIG. 8B) of the p-type base region 22 (D₁₁>D₃=D₆). The eleventh depth D₁₁ may be larger than the first depth D₁ (see FIG. 8B) of the first diffusion region 17 and the fourth depth D₄ (see FIG. 8B) of the second diffusion region 20 (D₁₁>D₁=D₄). The eleventh depth D₁₁ may be larger than the seventh depth D₇ (see FIG. 10) of the bottom 51a of the first diffusion layer 51 (D₁₁>D₇). The modification (third modification) shown in FIG. 28 may be combined with any of the embodiments (including the modifications) other than the second embodiment.

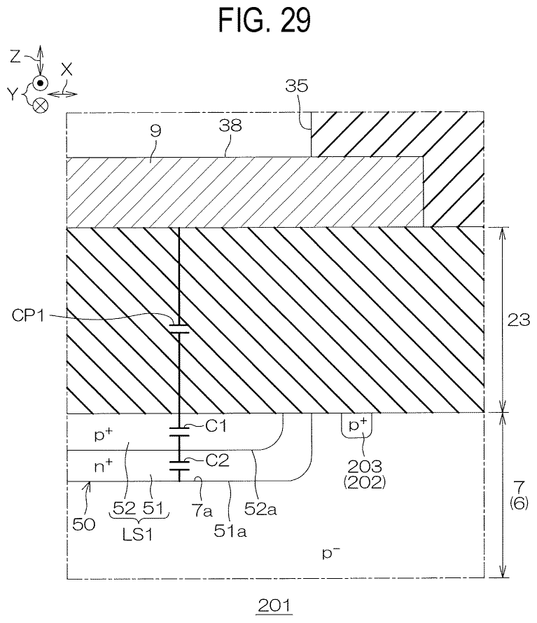

As shown in FIG. 29, the p-type high concentration region 203 may not be in contact with the first diffusion layer 51 (laminated structure LS1) and may be formed with a gap from the peripheral edge of the first diffusion layer 51 (laminated structure LS1). The modification (fourth modification) shown in FIG. 29 may be combined with any of the embodiments (including the modifications) other than the second embodiment.

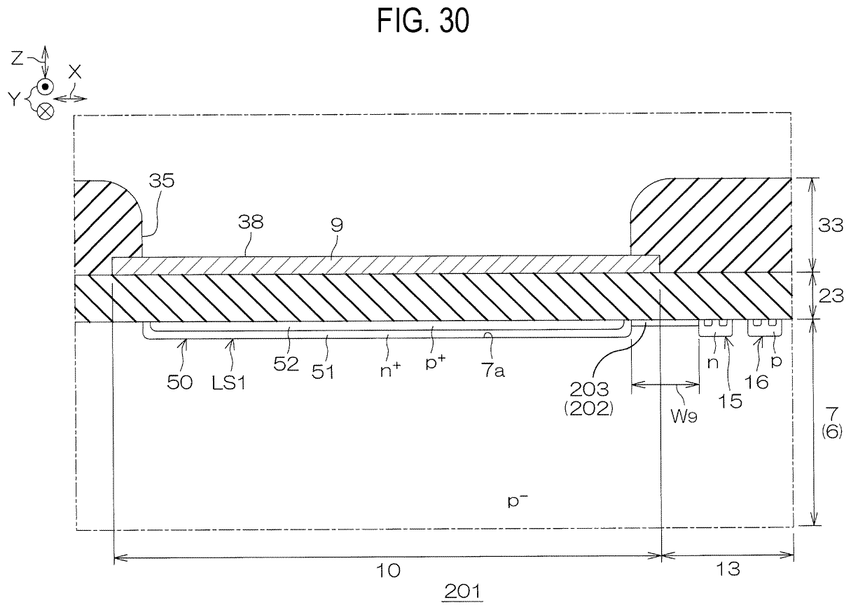

In addition, as shown in FIG. 30, when the first thyristor structure 15 (i.e., the n-type first diffusion region 17 (see FIG. 8A)) is adjacent to the laminated parasitic capacitance former 50 (laminated structure LS1), the p-type high concentration region 203 may be in contact with the first thyristor structure 15 (first diffusion region 17 (see FIG. 8A)). In the example of FIG. 30, the p-type high concentration region 203 is in contact with both the first diffusion layer 51 (laminated structure LS1) and the first thyristor structure 15 (first diffusion region 17 (see FIG. 8A)). The modification (fifth modification) shown in FIG. 30 may be combined with any of the embodiments (including the modifications) other than the second embodiment.

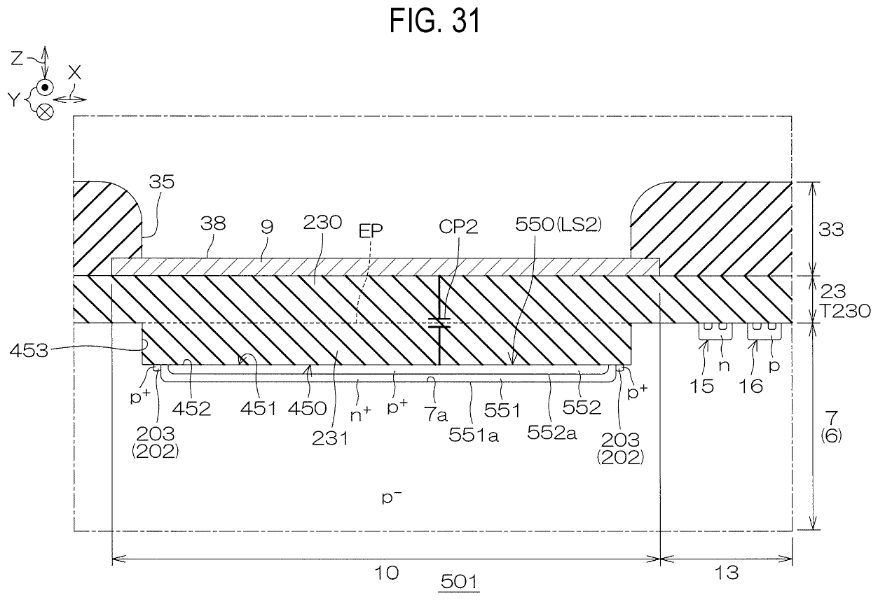

As shown in FIG. 31, the p-type high concentration region 203 (isolator 202) according to the second embodiment may be applied to the semiconductor device 501 according to the fifth embodiment. In this case, the p-type high concentration region 203 is formed in the bottom surface 452 of the first trench 451. The modification (sixth modification) shown in FIG. 31 may be combined with any of the embodiments (including the modifications) other than the second embodiment.

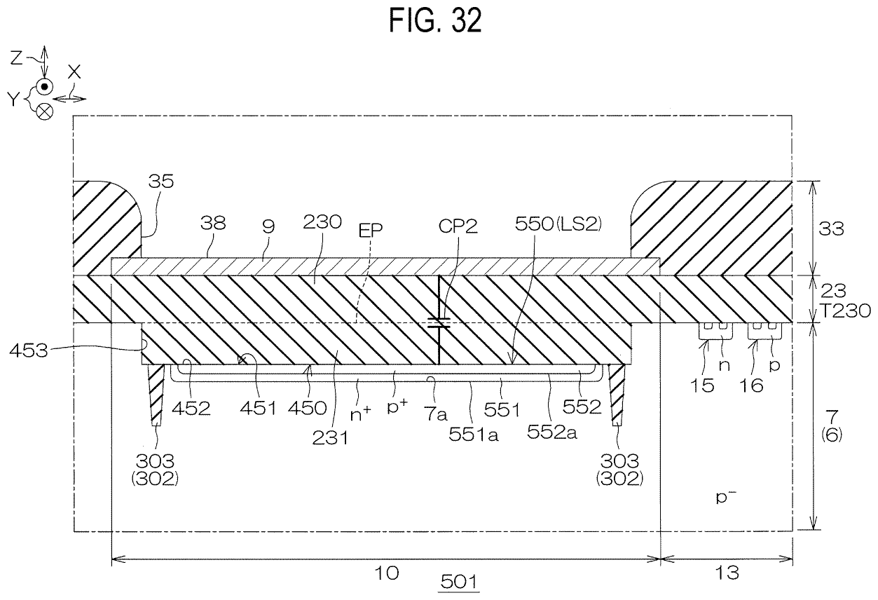

As shown in FIG. 32, the insulating trench structure 303 (isolator 302) according to the third embodiment may be applied to the semiconductor device 501 according to the fifth embodiment. In this case, the insulating trench structure 303 is formed on the bottom surface 452 of the first trench 451. The modification (seventh modification) shown in FIG. 32 may be combined with any of the embodiments (including the modifications) other than the second embodiment.

In addition, the semiconductor layer 6 may be a laminated structure of the semiconductor substrate 7 and a semiconductor layer (e.g., epitaxial layer), instead of being formed by the semiconductor substrate 7 only. In this case, the first thyristor structure 15, the second thyristor structure 16, the laminated parasitic capacitance formers 50 and 550, the trench parasitic capacitance former 450, and the like may be formed in the semiconductor layer (e.g., epitaxial layer).

In the above-described embodiments, the example in which the first conductivity type is p-type and the second conductivity type is n-type has been described. However, the first conductivity type may be n-type and the second conductivity type may be p-type. A specific configuration in this case can be obtained by replacing the p-type region with an n-type region and the n-type region with a p-type region in the above description and the accompanying drawings.

The embodiments of the present disclosure are exemplary in all respects and should not be construed as being limitative, and are intended to include modifications in all respects.

The features supplementarily noted below can be extracted from the descriptions of this specification and the drawings. In the following, alphanumeric characters in parentheses represent corresponding components in the above-described embodiments, but are not intended to limit the scope of each clause to the embodiments.

### Supplementary Note A-1

A semiconductor device (1, 201, 301, 401, 501), comprising:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) so as to cover the first diffusion region (17) and the second diffusion region (20);
a first pad (9) disposed on the insulating layer (23) and electrically connected to the first diffusion region (17); and
an internal parasitic capacitance former (50, 450, 550) formed in a surface layer portion of the semiconductor layer (6), and configured to generate an internal parasitic capacitance (C1, C2, C3, C4, CT) between a facing portion (7a) of the semiconductor layer (6) that faces the first pad (9) across the insulating layer (23) and the main surface (3) or an extension surface (EP) that is flush with the main surface (3),
wherein the first pad (9) forms a first parasitic capacitance (CP1), which is connected in series to the internal parasitic capacitance (C1, C2, C3, C4, CT), at a location between the first pad (9) and an upper portion (230) of the insulating layer (23) formed above the main surface (3) or the extension surface (EP).

Since the first pad (9) is at the same potential as the first diffusion region (17) of the second conductivity type, a parasitic capacitance is formed between the first pad (9) and the semiconductor layer (6) of the first conductivity type.

With this configuration, the internal parasitic capacitance former (50, 450, 550) is formed in the surface layer portion of the semiconductor layer (6). The internal parasitic capacitance former (50, 450, 550) forms the internal parasitic capacitance (C1, C2, C3, C4, CT) between the facing portion (7a) and the main surface (3) or the extension surface (EP). Further, the first parasitic capacitance (CP1) connected in series to the internal parasitic capacitance (C1, C2, C3, C4, CT) is formed between the first pad (9) and the upper portion (230). Thus, it is possible to reduce the parasitic capacitance around the first pad (9) (the parasitic capacitance of the portion between the first pad and the facing portion) compared to a case where the internal parasitic capacitance former (50, 450, 550) is not formed in the surface layer portion of the semiconductor layer (6).

### Supplementary Note A-2

The semiconductor device (1, 201, 301, 501) of Supplementary Note A-1, wherein the internal parasitic capacitance former (50, 450, 550) has a laminated structure (LS1, LS2) of a first diffusion layer (51, 551) of the second conductivity type, which is formed in the surface layer portion of the semiconductor layer (6) to face the first pad (9) with the insulating layer (23) interposed between the first diffusion layer (51, 551) and the first pad (9), and a second diffusion layer (52, 552) of the first conductivity type, which is formed in a surface layer portion of the first diffusion layer (51, 551), and includes a laminated parasitic capacitance former (50, 550) that forms a laminated parasitic capacitance (C1, C2, C3, C4) between the semiconductor layer (6) and a surface of the laminated structure (LS1, LS2).

With this configuration, the laminated structure (LS1, LS2) having the first diffusion layer (51, 551) and the second diffusion layer (52, 552) is formed in the surface layer portion of the semiconductor layer (6). A laminated parasitic capacitance (first laminated parasitic capacitance (CL1)) is formed between the second diffusion layer (52, 552) of the first conductivity type and the first diffusion layer (51, 551) of the second conductivity type, and a laminated parasitic capacitance (second laminated parasitic capacitance (CL2)) is formed between the first diffusion layer (51) of the second conductivity type and the semiconductor layer (6) of the first conductivity type. Further, a first parasitic capacitance (CP1) connected in series to the laminated parasitic capacitance (C1, C2, C3, C4) is formed between the first pad (9) and the upper portion (230). Thus, it is possible to reduce the parasitic capacitance around the first pad (9) (the parasitic capacitance of the portion between the first pad and the facing portion) compared to a case where the laminated structure (LS1 or LS2) is not formed in the surface layer portion of the semiconductor layer (6).

### Supplementary Note A-3

The semiconductor device (1, 201, 301, 501) of Supplementary Note A-2, wherein the first diffusion layer (51, 551) is formed in the main surface (3).

### Supplementary Note A-4

The semiconductor device (1, 201, 301, 501) of Supplementary Note A-2 or Supplementary Note A-3, wherein a depth (D₈) of a bottom (52a, 552a) of the second diffusion layer (52, 552) is shallower than a bottom (51a, 551a) of the first diffusion layer (51, 551).

### Supplementary Note A-5

The semiconductor device (1, 201, 301, 501) of any one of Supplementary Note A-2 to Supplementary Note A-4, wherein a depth (D₇) of a bottom (51a, 551a) of the first diffusion layer (51, 551) is equal to a depth (D₁) of a bottom (17a) of the first diffusion region (17).

### Supplementary Note A-6

The semiconductor device (1, 201, 301, 501) of any one of Supplementary Note A-2 to Supplementary Note A-5, wherein a depth (D₈) of a bottom (52a, 552a) of the second diffusion layer (52, 552) is shallower than a bottom (17a) of the first diffusion region (17).

### Supplementary Note A-7

The semiconductor device (1, 201, 301, 501) of any one of Supplementary Note A-2 to Supplementary Note A-6, further comprising an isolator (202, 302) formed between the first diffusion region (17) and the first diffusion layer (51, 551), and configured to isolate the first diffusion region (17) from the first diffusion layer (51, 551).

### Supplementary Note A-8

The semiconductor device (1, 201, 301, 401, 501) of Supplementary Note A-7, wherein the isolator (202, 302) includes a high concentration region (203) of the first conductivity type having a first conductivity type impurity concentration higher than that of the semiconductor layer (6).

### Supplementary Note A-9

The semiconductor device (1, 201, 301, 501) of Supplementary Note A-8, wherein the first conductivity type impurity concentration of the high concentration region (203) is higher than a first conductivity type impurity concentration of the second diffusion region (20).

### Supplementary Note A-10

The semiconductor device (1, 201, 301, 501) of Supplementary Note A-7, wherein the isolator has an insulating trench structure (303) including an insulating trench (304) formed in the surface layer portion of the semiconductor layer (6) and an insulator (305) embedded in the insulating trench (304).

### Supplementary Note A-11

The semiconductor device (1, 201, 301, 501) of Supplementary Note A-10, wherein a depth (D₁₀) of the insulating trench structure (303) is deeper than a bottom (51a, 551a) of the first diffusion layer (51, 551).

### Supplementary Note A-12

The semiconductor device (1, 201, 301, 501) of any one of Supplementary Note A-2 to Supplementary Note A-11, wherein the laminated structure (LS1, LS2) further includes a third diffusion layer (53) of the second conductivity type, which is formed in a surface layer portion of the second diffusion layer (52, 552).

### Supplementary Note A-13

The semiconductor device (1, 201, 301, 501) of any one of Supplementary Note A-2 to Supplementary Note A-12, wherein the first pad (9) has an electrode surface (38) on which a connector (W) is capable of being disposed, and the laminated parasitic capacitance former (50, 550) overlaps with the electrode surface (38) via the insulating layer (23) in a plan view.

### Supplementary Note A-14

The semiconductor device (1, 201, 301, 501) of any one of Supplementary Note A-1 to Supplementary Note A-13, wherein the semiconductor layer (6) is a semiconductor substrate (7).

### Supplementary Note A-15

A semiconductor device (1, 201, 301, 501), comprising:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) to cover the first diffusion region (17) and the second diffusion region (20);
a first pad (9) disposed on the insulating layer (23) and electrically connected to the first diffusion region (17); and
a laminated parasitic capacitance former (50, 550) having a laminated structure (LS1, LS2) of a first diffusion layer (51, 551) of the second conductivity type, which is formed to face the first pad (9) with the insulating layer (23) interposed between the first diffusion layer (51, 551) and the first pad (9), and a second diffusion layer (52, 552) of the first conductivity type, which is formed in a surface layer portion of the first diffusion layer (51, 551), in a surface layer portion of the semiconductor layer (6), and configured to generate a laminated parasitic capacitance (C1, C2, C3, C4) between the semiconductor layer (6) and a surface of the laminated structure (LS1, LS2),
wherein the first pad (9) forms a second parasitic capacitance (CP1, CP2), which is connected in series to the laminated parasitic capacitances (C1, C2, C3, C4), at a location between the first pad (9) and the insulating layer (23).

The first pad (9) is at the same potential as the first diffusion region (17) of the second conductivity type. Therefore, a parasitic capacitance is formed between the first pad (9) and the semiconductor layer (6) of the first conductivity type.

With this configuration, the laminated structure (LS1, LS2) having the first diffusion layer (51, 551) and the second diffusion layer (52, 552) is formed in the surface layer portion of the semiconductor layer (6). A laminated parasitic capacitance (first laminated parasitic capacitance (CL1)) is formed between the second diffusion layer (52, 552) of the first conductivity type and the first diffusion layer (51, 551) of the second conductivity type, and a laminated parasitic capacitance (second laminated parasitic capacitance (CL2)) is formed between the first diffusion layer 51 of the second conductivity type and the semiconductor layer (6) of the first conductivity type. Further, the second parasitic capacitance connected in series to the laminated parasitic capacitance (C1, C2, C3, C4) is formed between the first pad (9) and the insulating layer (23). Thus, it is possible to reduce the parasitic capacitance around the first pad (9) (the parasitic capacitance of the portion between the first pad and the facing portion) compared to a case where the laminated structure (LS1, LS2) is not formed in the surface layer portion of the semiconductor layer (6).

### Supplementary Note B-1

A semiconductor device (401, 501), comprising:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) to cover the first diffusion region (17) and the second diffusion region (20);
a first pad (9) disposed on the insulating layer (23) and electrically connected to the first diffusion region (17); and
an internal parasitic capacitance former (450, 550) formed in a surface layer portion of the semiconductor layer (6), and configured to generate an internal parasitic capacitance (C1, C2, C3, C4, CT) between a facing portion (7a) of the semiconductor layer (6) that faces the first pad (9) across the insulating layer (23) and the main surface (3) or an extension surface (EP) that is flush with the main surface (3),
wherein the internal parasitic capacitance former (450, 550) is a trench parasitic capacitance former (450) having a first trench (451) formed in the main surface (3) and an intra-trench insulating layer (231) of the insulating layer (23) embedded in the first trench (451), and configured to form a trench parasitic capacitance (CT) between the extension surface (EP) in the first trench (451) and the facing portion (7a) formed in a bottom surface (452) of the first trench (451), and
wherein the first pad (9) forms a first parasitic capacitance (CP1), which is connected in series to the trench parasitic capacitances (CT), at a location between the first pad (9) and an upper portion (230) of the insulating layer (23) formed above the main surface (3) or the extension surface (EP).

With this configuration, the trench parasitic capacitance former (450) is formed in the surface layer portion of the semiconductor layer (6). The trench parasitic capacitance former (450) forms the trench parasitic capacitance (CT) between the facing portion (7a) and the main surface (3) or the extension surface (EP). Further, the first parasitic capacitance (CP1) connected in series to the trench parasitic capacitance (CT) is formed between the first pad (9) and the upper portion (230). Thus, it is possible to reduce the parasitic capacitance around the first pad (9) (the parasitic capacitance of the portion between the first pad and the facing portion) compared to a case where the trench parasitic capacitance former (450) is not formed in the surface layer portion of the semiconductor layer (6).

### Supplementary Note B-2

The semiconductor device (401, 501) of Supplementary Note B-1, wherein the bottom surface (452) of the first trench (451) is a flat surface parallel to the main surface (3).

### Supplementary Note B-3

The semiconductor device (401, 501) of Supplementary Note B-1 or Supplementary Note B-2, wherein a depth (DT) of the bottom surface (452) of the first trench (451) is deeper than a bottom (17a) of the first diffusion region (17).

### Supplementary Note B-4

The semiconductor device (401, 501) of any one of Supplementary Note B-1 to Supplementary Note B-3, wherein the first pad (9) has an electrode surface (38) on which a connector (W) is capable of being disposed, and the trench parasitic capacitance former (450) overlaps with the electrode surface (38) via the insulating layer (23) in a plan view.

### Supplementary Note B-5

The semiconductor device (501) of any one of Supplementary Note B-1 to Supplementary Note B-4, wherein the internal parasitic capacitance former (450, 550) further includes a laminated parasitic capacitance former (550) having a laminated structure (LS2) of a first diffusion layer (51, 551) of the second conductivity type, which is formed to face the first pad (9) with the insulating layer (23) interposed between first diffusion layer (51, 551) and the first pad (9), and a second diffusion layer (52, 552) of the first conductivity type, which is formed in a surface layer portion of the first diffusion layer (51, 551), in the surface layer portion of the semiconductor layer (6), and configured to form a laminated parasitic capacitance (C1, C2, C3, C4) between the semiconductor layer (6) and a surface of the laminated structure (LS2),

### Supplementary Note B-6

The semiconductor device (501) of Supplementary Note B-5, wherein a depth (D₈) of a bottom (52a, 552a) of the second diffusion layer (52, 552) is shallower than a bottom (51a, 551a) of the first diffusion layer (51, 551).

### Supplementary Note B-7

The semiconductor device (501) of Supplementary Note B-5 or Supplementary Note B-6, wherein a depth (D₇) of a bottom (51a, 551a) of the first diffusion layer (51, 551) is equal to a depth (D₁) of a bottom (17a) of the first diffusion region (17).

### Supplementary Note B-8

The semiconductor device (501) of any one of Supplementary Note B-5 to Supplementary Note B-7, wherein a depth (D₈) of a bottom (52a, 552a) of the second diffusion layer (52, 552) is shallower than a bottom (17a) of the first diffusion region (17).

### Supplementary Note B-9

The semiconductor device (501) of any one of Supplementary Note B-5 to Supplementary Note B-8, further comprising an isolator (202, 302) formed between the first diffusion layer (51, 551) and a peripheral edge of the bottom surface (452) of the first trench (451), and configured to isolate the first diffusion region (17) from the first diffusion layer (51, 551).

### Supplementary Note B-10

The semiconductor device (501) of Supplementary Note B-9, wherein the isolator (202, 302) includes a high concentration region (203) of the first conductivity type having a first conductivity type impurity concentration higher than that of the semiconductor layer (6).

### Supplementary Note B-11

The semiconductor device (501) of Supplementary Note B-10, wherein the first conductivity type impurity concentration of the high concentration region (203) is higher than a first conductivity type impurity concentration of the second diffusion region (20).

### Supplementary Note B-12

The semiconductor device (501) of Supplementary Note B-9, wherein the isolator includes an insulating trench structure (303) having an insulating trench (304) formed in the bottom surface (452) of the first trench (451) and an insulator (305) embedded in the insulating trench (304).

### Supplementary Note B-13

The semiconductor device (501) of Supplementary Note B-12, wherein a depth (D₁₀) of the insulating trench structure (303) is deeper than a bottom (51a, 551a) of the first diffusion layer (51, 551).

### Supplementary Note B-14

The semiconductor device (401, 501) of any one of Supplementary Note B-1 to Supplementary Note B-13, wherein the semiconductor layer (6) is a semiconductor substrate (7).

### Supplementary Note B-15

A semiconductor device (401, 501), comprising:
a semiconductor layer (6) of a first conductivity type having a main surface (3);
a first diffusion region (17) of a second conductivity type formed in a surface layer portion of the main surface (3);
a second diffusion region (20) of the first conductivity type formed in the surface layer portion of the main surface (3);
an insulating layer (23) formed on the main surface (3) to cover the first diffusion region (17) and the second diffusion region (20);
a first pad (9) disposed on the insulating layer (23) and electrically connected to the first diffusion region (17); and
a first trench (451) formed in the main surface (3) to face the first pad with the insulating layer interposed between the first trench (451) and the first pad (9), and embedded with a portion (231) of the insulating layer (23),
wherein the first pad (9) forms a third parasitic capacitance (CP2) between the first pad (9) and a facing portion (7a) formed in a bottom surface (452) of the first trench (451) to face the first pad (9) with the insulating layer (23) interposed between the first pad (9) and the facing portion (7a).

With this configuration, the trench parasitic capacitance former (450) is formed in the surface layer portion of the semiconductor layer (6). Compared to a case where the first trench (451) is not formed in the first main surface (3), a distance between the first pad (9) and the facing portion (7a) can be kept large. Since a parasitic capacitance is inversely proportional to a distance between electrodes, the parasitic capacitance around the first pad (9) can be reduced by keeping the distance between the first pad (9) and the facing portion (7a) large.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor layer of a first conductivity type having a main surface;
a first diffusion region of a second conductivity type formed in a surface layer portion of the main surface;
a second diffusion region of the first conductivity type formed in the surface layer portion of the main surface;
an insulating layer formed on the main surface to cover the first diffusion region and the second diffusion region;
a first pad disposed on the insulating layer and electrically connected to the first diffusion region; and
an internal parasitic capacitance former formed in a surface layer portion of the semiconductor layer, and configured to generate an internal parasitic capacitance between a facing portion of the semiconductor layer that faces the first pad across the insulating layer and the main surface or an extension surface that is flush with the main surface,
wherein the first pad forms a first parasitic capacitance, which is connected in series to the internal parasitic capacitance, at a location between the first pad and an upper portion of the insulating layer formed above the main surface or the extension surface.

2. The semiconductor device of claim 1, wherein the internal parasitic capacitance former has a laminated structure of a first diffusion layer of the second conductivity type, which is formed in the surface layer portion of the semiconductor layer to face the first pad with the insulating layer interposed between the first diffusion layer and the first pad, and a second diffusion layer of the first conductivity type, which is formed in a surface layer portion of the first diffusion layer, and includes a laminated parasitic capacitance former that forms a laminated parasitic capacitance between the semiconductor layer and a surface of the laminated structure.

3. The semiconductor device of claim 2, wherein the first diffusion layer is formed in the main surface.

4. The semiconductor device of claim 2, wherein a depth of a bottom of the second diffusion layer is shallower than a bottom of the first diffusion layer.

5. The semiconductor device of claim 2, wherein a depth of a bottom of the first diffusion layer is equal to a depth of a bottom of the first diffusion region.

6. The semiconductor device of claim 2, wherein a depth of a bottom of the second diffusion layer is shallower than a bottom of the first diffusion region.

7. The semiconductor device of claim 2, further comprising an isolator formed between the first diffusion region and the first diffusion layer, and configured to isolate the first diffusion region from the first diffusion layer.

8. The semiconductor device of claim 7, wherein the isolator includes a high concentration region of the first conductivity type having a first conductivity type impurity concentration higher than that of the semiconductor layer.

9. The semiconductor device of claim 8, wherein the first conductivity type impurity concentration of the high concentration region is higher than a first conductivity type impurity concentration of the second diffusion region.

10. The semiconductor device of claim 7, wherein the isolator has an insulating trench structure including an insulating trench formed in the surface layer portion of the semiconductor layer and an insulator embedded in the insulating trench.

11. The semiconductor device of claim 10, wherein a depth of the insulating trench structure is deeper than a bottom of the first diffusion layer.

12. The semiconductor device of claim 2, wherein the laminated structure further includes a third diffusion layer of the second conductivity type, which is formed in a surface layer portion of the second diffusion layer.

13. The semiconductor device of claim 2, wherein the first pad has an electrode surface on which a connector is capable of being disposed, and the laminated parasitic capacitance former overlaps with the electrode surface via the insulating layer in a plan view.

14. The semiconductor device of claim 1, wherein the semiconductor layer is a semiconductor substrate.

15. A semiconductor device, comprising:
a semiconductor layer of a first conductivity type having a main surface;
a first diffusion region of a second conductivity type formed in a surface layer portion of the main surface;
a second diffusion region of the first conductivity type formed in the surface layer portion of the main surface;
an insulating layer formed on the main surface to cover the first diffusion region and the second diffusion region;
a first pad disposed on the insulating layer and electrically connected to the first diffusion region; and
a laminated parasitic capacitance former having a laminated structure of a first diffusion layer of the second conductivity type, which is formed to face the first pad with the insulating layer interposed between the first diffusion layer and the first pad, and a second diffusion layer of the first conductivity type, which is formed in a surface layer portion of the first diffusion layer, in a surface layer portion of the semiconductor layer, and configured to generate a laminated parasitic capacitance between the semiconductor layer and a surface of the laminated structure,
wherein the first pad forms a second parasitic capacitance, which is connected in series to the laminated parasitic capacitance, at a location between the first pad and the insulating layer.
